(19) United States
(12) Patent Application Publication
(10) Pub. No.: US 2026/0013330 A1
(43) Pub. Date: Jan. 8, 2026

(54) DISPLAY DEVICE, METHOD OF MANUFACTURING THE DISPLAY DEVICE AND DISPLAY SYSTEM

(71) Applicant: Samsung Display Co., LTD., Yongin-si (KR)

(72) Inventors: Ju Won YOON, Yongin-si (KR); Jae Been LEE, Yongin-si (KR); Lok Gam JUNG, Yongin-si (KR)

(21) Appl. No.: 19/005,370

(22) Filed: Dec. 30, 2024

(30) Foreign Application Priority Data
Jul. 3, 2024 (KR) 10-2024-0087225

(51) Int. Cl. H10K 59/122; H10K 59/12

(52) U.S. Cl. CPC H10K 59/122; H10K 59/1201

(57) ABSTRACT

A display device includes a first electrode, a protective layer on the first electrode, a first pixel defining layer on the protective layer, a first void between the first electrode and the first pixel defining layer, a second pixel defining layer on the first pixel defining layer, a third pixel defining layer on the second pixel defining layer, a second void between the first pixel defining layer and the third pixel defining layer, and a light emitting structure on the first electrode, the first pixel defining layer, the second pixel defining layer, and the third pixel defining layer. A thickness of a first side of the first void is greater than a thickness of a second side of the first void.

### CROSS-REFERENCE TO RELATED APPLICATION

The present application claims priority to and the benefit of Korean Patent Application No. 10-2024-0087225, filed on Jul. 3, 2024, in the Korean Intellectual Property Office, the entire disclosure of which is incorporated herein by reference.

### BACKGROUND

### 1. Field

Embodiments of the present disclosure described herein are related to a display device, a method of manufacturing the display device and a display system.

### 2. Description of the Related Art

Recently, as consumer interest in information displays increases, research and development of display devices are being conducted.

The information disclosed in this Background section is intended to enhance understanding of the background of the disclosure and therefore it may contain information that does not constitute prior art.

### SUMMARY

Aspects according to one or more embodiments of the present disclosure are directed toward a display device having improved reliability and a method of manufacturing the display device.

Additional aspects will be set forth in part in the description which follows and, in part, will be apparent from the description, or may be learned by practice of the presented embodiments of the disclosure.

In one or more embodiments of the present disclosure, a display device including: a first electrode; a protective layer on the first electrode; a first pixel defining layer on the protective layer; a first void between the first electrode and the first pixel defining layer; a second pixel defining layer on the first pixel defining layer; a third pixel defining layer on the second pixel defining layer; a second void between the first pixel defining layer and the third pixel defining layer; and a light emitting structure on the first electrode, the first pixel defining layer, the second pixel defining layer, and the third pixel defining layer, wherein a thickness of a first side of the first void is thicker (or greater) than a thickness of a second side of the first void.

The thickness of the first side of the first void may be equal to a thickness of the protective layer.

A thickness of the second void may be thicker (or greater) than the thickness of the first side of the first void.

A width of the first void may be greater than a thickness of the protective layer.

An edge of the first pixel defining layer may be spaced and/or apart (e.g., spaced apart or separated) from the first electrode.

A distance between the edge of the first pixel defining layer and the first electrode may be 200 Å or less.

An edge of the first pixel defining layer may be in contact with the first electrode.

The first side of the first void may be defined by the protective layer.

A first side of the second void may be defined by the second pixel defining layer.

A second side of the second void may be defined by the light emitting structure.

The light emitting structure may be at least partially separated by the second void.

In one or more embodiments of the present disclosure, a method of manufacturing a display device includes: forming a sacrificial layer on a first electrode; forming a pixel defining layer on the sacrificial layer; forming a protective layer by forming an opening exposing the first electrode on the sacrificial layer; and forming a light emitting structure on the first electrode and the pixel defining layer, wherein, in the forming of the protective layer, at least a portion of the pixel defining layer is on the first electrode.

A first void may be formed between the first electrode and the pixel defining layer.

A width of the first void may be formed to be greater than a thickness of the protective layer.

The sacrificial layer may be formed of aluminum or an aluminum alloy.

The forming of the pixel defining layer may include: sequentially forming a first layer, a second layer, and a third layer on the sacrificial layer; forming a second pixel defining layer and a third defining layer by etching the second layer and the third layer; and forming a first pixel defining layer by etching the first layer.

A second void may be formed between the first pixel defining layer and the third pixel defining layer.

The light emitting structure may be at least partially separated by the second void.

In the forming of the protective layer, the first pixel defining layer may be on the first electrode.

In the forming of the protective layer, an edge of the first pixel defining layer may be in contact with the first electrode.

In one or more embodiments of the present disclosure, a display system including: a display device comprises a first electrode; a protective layer on the first electrode; a first pixel defining layer on the protective layer; a first void between the first electrode and the first pixel defining layer; a second pixel defining layer on the first pixel defining layer; a third pixel defining layer on the second pixel defining layer; a second void between the first pixel defining layer and the third pixel defining layer; and a light emitting structure on the first electrode, the first pixel defining layer, the second pixel defining layer, and the third pixel defining layer, wherein a thickness of a first side of the first void is greater than a thickness of a second side of the first void.

The display system is at least one selected from the group consisting of a portable computer, a mobile phone, a smartphone, a tablet personal computer (PC), a smart watch, a watch phone, a portable multimedia player (PMP), a navigation system, an ultra mobile computer (UMPC) a head mounted display (HMD) device, a virtual reality (VR) device, a mixed reality (MR) device, and an augmented reality (AR) device.

### BRIEF DESCRIPTION OF THE DRAWINGS

Example embodiments will now be described in more detail hereinafter with reference to the accompanying drawings; however, they may be embodied in different forms and should not be construed as being limited to the embodiments set forth herein. Rather, these embodiments are provided so that the present disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating aspects of a display device according to some embodiments.

FIG. 2 is a block diagram illustrating aspects of any one of sub-pixels shown in FIG. 1 according to some embodiments.

FIG. 3 is a circuit diagram illustrating further details of the sub-pixel shown in FIG. 2 according to some embodiments.

FIG. 4 is a plan view illustrating further details of a display panel shown in FIG. 1 according to some embodiments.

FIG. 5 is an exploded perspective view illustrating further details of the display panel shown in FIG. 4 according to some embodiments.

FIG. 6 is a plan view illustrating further details of any one of pixels shown in FIG. 5 according to some embodiments.

FIG. 7 is a sectional view illustrating further details taken along the line I-I′ shown in FIG. 6.

FIGS. 8 and 9 are cross-sectional views illustrating further details of a protective layer and a pixel defining layer, which are shown in FIG. 7 according to some embodiments.

FIG. 10 is a cross-sectional view illustrating aspects of a light emitting structure included in any one of first to third light emitting elements shown in FIG. 7 according to some embodiments.

FIG. 11 is a cross-sectional view illustrating aspects of the light emitting structure included in the one of the first to third light emitting elements shown in FIG. 7 according to some embodiments.

FIG. 12 is a plan view illustrating further details of the one of the pixels shown in FIG. 5 according to some embodiments.

FIG. 13 is a plan view illustrating further details of the one of the pixels shown in FIG. 5 according to some embodiments.

FIG. 14 is a block diagram illustrating aspects of a display system according to some embodiments.

FIG. 15 is a perspective view illustrating an application example of the display system shown in FIG. 14.

FIG. 16 is a view illustrating a head-mounted display device shown in FIG. 15, which is worn by a user.

FIGS. 17-24 are cross-sectional views illustrating aspects of a method of manufacturing a display device according to some embodiments of the present disclosure.

### DETAILED DESCRIPTION

Hereinafter, aspects of some embodiments of the present disclosure will be described in more detail with reference to the accompanying drawings. In the description below, only a necessary part to understand an operation according to the present disclosure is described and the descriptions of other parts may not be provided in order to not unnecessarily obscure subject matters of the present disclosure. In addition, the present disclosure is not limited to example embodiments described herein, but may be embodied in various different forms. Rather, example embodiments described herein are provided to thoroughly and completely describe the disclosed contents and to sufficiently transfer the ideas of the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe one or more suitable elements, these elements should not be limited by these terms. These terms are only used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of example embodiments (and an intermediate structure) of the present disclosure, so that changes in a shape as shown due to, for example, manufacturing technology and/or a tolerance may be expected. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

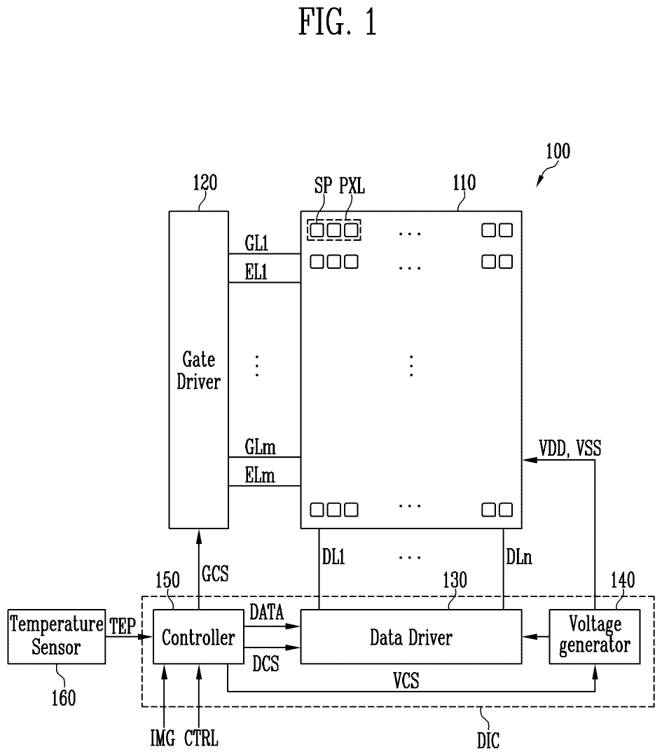

FIG. 1 is a block diagram illustrating aspects of a display device according to some embodiments.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

Each of the sub-pixels SP may include at least one light emitting element configured to generate light. Accordingly, each of the sub-pixels SP may be configured to generate light of a specific color such as red, green, blue, cyan, magenta or yellow. Two or more sub-pixels among the sub-pixels SP may constitute one pixel PXL. For example, three sub-pixels SP may constitute one pixel PXL as shown in FIG. 1.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. In one or more embodiments, the gate control signal GCS may include a start signal indicating a start of each frame, a horizontal synchronization signal for outputting gate signals in synchronization with timings at which data signals are applied, and the like.

In one or more embodiments, first to mth light emitting control lines EL1 to ELm connected to the sub-pixels SP in the row direction may be further provided. The gate driver 120 may include an emission control driver configured to control the first to mth emission control lines EL1 to ELm, and the emission control driver may operate under the control of the controller 150.

The gate driver 120 may be at one side of the display panel 110. However, embodiments are not limited thereto. For example, the gate driver 120 may be divided into two or more drivers which are physically and/or logically divided, and these drivers may be at one side of the display panel 110 and the other side of the display panel 110, which is opposite to the one side. For example, one of the two or more drivers may be at one side of the display panel 110 and another one of the two or more drivers may be at an opposite side of the display panel 110. As such, according to some embodiments, the gate driver 120 may be included in one or more suitable forms at the periphery of the display panel 110.

The data driver 130 may be connected to the sub-pixels SP arranged in a column direction through the first to nth data lines DL1 to DLn. The data driver 130 may be configured to receive image data DATA and a data control signal DCS from the controller 150. The data driver 130 may operate in response to the data control signal DCS. In one or more embodiments, the data control signal DCS may include a source start pulse, a source shift clock, a source output enable signal, and the like.

The data driver 130 may be configured to apply data signals having grayscale voltages corresponding to the image data DATA to the first to nth data lines DL1 to DLn by using voltages from the voltage generator 140. When a gate signal is applied to each of the first to mth gate lines GL1 to GLm, data signals corresponding to the image data DATA may be applied to the data lines DL1 to DLm. Accordingly, corresponding sub-pixels SP may be configured to generate light corresponding to the data signals. Accordingly, an image may be displayed on the display panel 110.

In one or more embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate a plurality of voltages by receiving an input voltage from an outside of the display device 100, adjusting the received voltage, and regulating the adjusted voltage.

The voltage generator 140 may be configured to generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the voltage level of the first power voltage VDD. In one or more embodiments, the first power voltage VDD or the second power voltage VSS may be provided by an external device of the display device 100.

Besides, the voltage generator 140 may be configured to generate various voltages. For example, the voltage generator 140 may be configured to generate an initialization voltage applied to the sub-pixels SP. For example, a reference voltage (e.g., a set or predetermined reference voltage) may be applied to the first to nth data lines DL1 to DLn in a sensing operation for sensing electrical characteristics of transistors and/or light emitting elements of the sub-pixels SP, and the voltage generator 140 may be configured to generate the reference voltage.

The controller 150 may control overall operations of the display device 100. The controller 150 may receive, from the outside, input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. In one or more embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In one or more embodiments, at least one of the data driver 130, the voltage generator 140, or the controller 150 may be provided as a component distinguished from the driver integrated circuit DIC.

The display device 100 may include at least one temperature sensor 160.

The temperature sensor 160 may be configured to sense a temperature at the periphery thereof and generate temperature data TEP indicating the sensed temperature. In one or more embodiments, the temperature sensor 160 may be adjacent to the display panel 110 and/or the driver integrated circuit DIC.

The controller 150 may control various operations of the display device 100 in response to the temperature data TEP. In one or more embodiments, the controller 150 may adjust the luminance of an image output from the display panel 100 in response to the temperature data TEP. For example, the controller 150 may control components such as the data driver 130 and/or the voltage generator 140, thereby adjusting data signals and the first and second power voltages VDD and VSS.

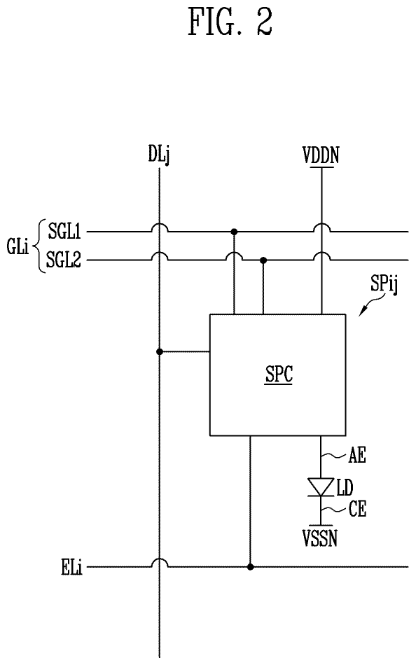

FIG. 2 is a block diagram illustrating further details of any one of the sub-pixels shown in FIG. 1 according to some embodiments. In FIG. 2, a sub-pixel SPij arranged on an ith row (i is an integer greater than or equal to 1 and smaller than or equal to m) and a jth column (j is an integer greater than or equal to 1 and smaller than or equal to n) among the sub-pixels SP shown in FIG. 1 is illustrated.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be a node transferring the first power voltage VDD shown in FIG. 1, and the second power voltage node VSSN may be a node transferring the second power voltage VSS shown in FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an ith gate line GLi among the first to mth gate lines GL1 to GLm shown in FIG. 1, an ith emission control line ELi among the first to mth emission control lines EL1 to ELm shown in FIG. 1, and a jth data line DLj among the first to nth data lines DL1 to DLn shown in FIG. 1. The sub-pixel circuit SPC may be configured to control the light emitting element LD according to signals received through these signal lines.

The sub-pixel circuit SPC may operate in response to a gate signal received through the ith gate line GLi. The ith gate line GLi may include one or more sub-gate lines. In one or more embodiments, as shown in FIG. 2, the ith gate line GLi may include first and second sub-gate lines SGL1 and SGL2. The sub-pixel circuit SPC may operate in response to gate signals received through the first and second sub-gate lines SGL1 and SGL2. As such, when the ith gate line GLi includes two or more sub-gate lines, the sub-pixel circuit SPC may operate in response to gate signals received through the corresponding sub-gate lines.

The sub-pixel circuit SPC may operate in response to an emission control signal received through the ith emission control line ELi. In one or more embodiments, the ith emission control line ELi may include one or more sub-emission control lines. When the ith emission control line ELi includes two or more sub-emission control lines, the sub-pixel circuit SPC may operate in response to emission control signals received through the corresponding emission control lines.

The sub-pixel circuit SPC may receive a data signal through the jth data line DLj. The sub-pixel circuit SPC may store a voltage corresponding to the data signal in response to at least one of the gate signals received through the first or second sub-gate lines SGL1 or SGL2. The sub-pixel circuit SPC may control a current flowing from the first power voltage node VDDN to the second power voltage node VSSN through the light emitting element LD according to the stored voltage in response to the emission control signal received through the ith emission control line ELi. Accordingly, the light emitting element LD may be configured to generate light with a luminance corresponding to the data signal.

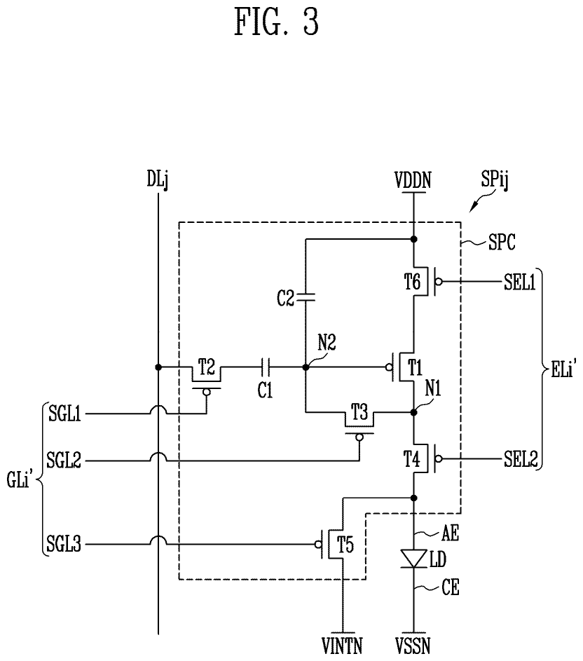

FIG. 3 is a circuit diagram illustrating further details of the sub-pixel shown in FIG. 2 according to some embodiments.

Referring to FIG. 3, a sub-pixel SPij may include a sub-pixel circuit SPC and a light emitting element LD.

The sub-pixel circuit SPC may be connected to an ith gate line GLi′, an ith emission control line ELi′, and a jth data line DLj. When comparing the ith gate line GLi′ with the ith gate line GLi shown in FIG. 2, the ith gate line GLi′ may further include a third sub-gate line SGL3. When comparing the ith emission control line ELi′ with the ith emission control line ELi shown in FIG. 2, the ith emission control line ELi′ may include a first sub-emission control line SEL1 and a second sub-emission control line SEL2.

The sub-pixel circuit SPC may include first to sixth transistors T1 to T6 and first and second capacitors C1 and C2.

The first transistor T1 may be connected between a first power voltage node VDDN and a first node N1. A gate of the first transistor T1 may be connected to a second node N2, and accordingly, the first transistor T1 may be turned on according to a voltage level of the second node N2. The first transistor T1 may be designated as a driving transistor.

The second transistor T2 may be connected between the jth data line DLj and the second node N2. A gate of the second transistor T2 may be connected to a first sub-gate line SGL1, and accordingly, the second transistor T2 may be turned on in response to a gate signal of the first sub-gate line SGL1. The second transistor T2 may be designated as a switching transistor.

The third transistor T3 may be connected between the first node N1 and the second node N2. A gate of the third transistor T3 may be connected to a second sub-gate line SGL2, and accordingly, the third transistor T3 may be turned on in response to a gate signal of the second sub-gate line SGL2.

The fourth transistor T4 may be connected between the first node N1 and an anode electrode AE of the light emitting element LD. A gate of the fourth transistor T4 may be connected to the second sub-emission control line SEL2, and accordingly, the fourth transistor T4 may be turned on in response to an emission control signal of the second sub-emission control line SEL2.

The fifth transistor T5 may be connected between the anode electrode AE of the light emitting element LD and an initialization voltage node VINTN. The initialization voltage node VINTN may be configured to transfer an initialization voltage. In one or more embodiments, the initialization voltage may be provided by the voltage generator 140 shown in FIG. 1. In one or more embodiments, the initialization voltage may be provided by an external device of the display device 100. A gate of the fifth transistor T5 may be connected to the third sub-gate line SGL3, and accordingly, the fifth transistor T5 may be turned on in response to a gate signal of the third sub-gate line SGL3.

The sixth transistor T6 may be connected between the first power voltage node VDDN and the first transistor T1. A gate of the sixth transistor T6 may be connected to the first sub-emission control line SEL1, and accordingly, the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

As such, the sub-pixel circuit SPC may include the first to sixth transistors T1 to T6 and the first and second capacitors C1 and C2. However, embodiments are not limited thereto. The sub-pixel circuit SPC may be implemented as any one of one or more suitable types of circuits each including a plurality of transistors and one or more capacitors. For example, the sub-pixel circuit SPC may include two transistors and one capacitor. In the sub-pixel circuit SPC according to some embodiments, the number of sub-gate lines included in the ith gate line GLi′ and the number of sub-emission control lines included in the ith emission control line ELi′ may vary.

The first to sixth transistors T1 to T6 may be P-type transistors. Each of the first to sixth transistors T1 to T6 may be a Metal Oxide Silicon Field Effect Transistor (MOSEFT). However, embodiments are not limited thereto. For example, at least one of the first to sixth transistors T1 to T6 may be an N-type transistor.

In one or more embodiments, the first to sixth transistors T1 to T6 may include an amorphous silicon semiconductor, a monocrystalline silicon semiconductor, a polycrystalline silicon semiconductor, an oxide semiconductor, and the like.

The light emitting element LD may include the anode electrode AE, a cathode electrode CE, and a light emitting layer. The light emitting layer may be between the anode electrode AE and the cathode electrode CE. After a data signal transferred through the jth data line DLj is reflected on a voltage of the second node N2, the fourth and sixth transistors T4 and T6 may be turned on when the emission control signals of the first and second sub-emission control lines SEL1 and SEL2 are enabled to a low level. The first transistor T1 may be turned on according to the voltage of the second node N2, and accordingly, a current may flow from the first power voltage node VDDN to a second power voltage node VSSN. The light emitting element LD may be configured to emit light according to an amount of the current flowing from the first power voltage node VDDN to the second power voltage node VSSN.

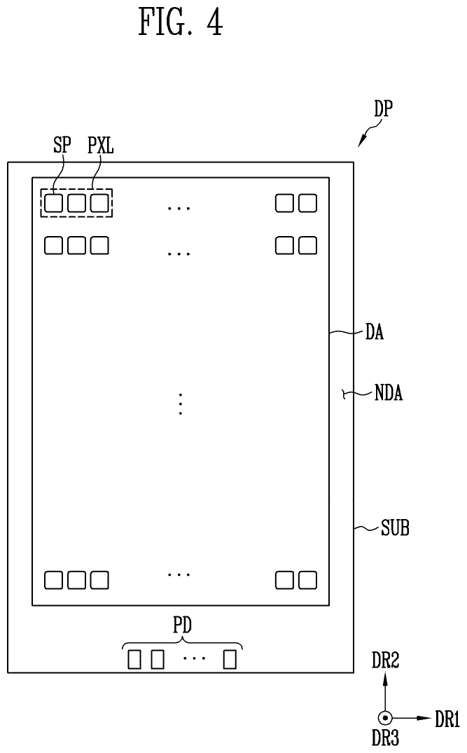

FIG. 4 is a plan view illustrating further details of the display panel shown in FIG. 1 according to some embodiments.

Referring to FIG. 4, an embodiment DP of the display panel 110 shown in FIG. 1 may include a display area DA and a non-display area NDA. The display panel DP may be configured to display an image through the display area DA. The non-display area NDA may be at the periphery of the display area DA. For example, the non-display area NDA may be around the display area DA and adjacent to the display area DA at one or more sides of the display area DA.

The display panel DP may include a substrate SUB, sub-pixels SP, and pads PD.

When the display panel DP is used as a display screen of a Head Mounted Display (HMD), a Virtual Reality (VR) device, a Mixed Reality (MR) device, an Augmented Reality (AR) device, and the like, the display panel DP may be located very close to eyes of a user. The sub-pixels SP having a relatively high degree of integration may be required or desired. In order to increase the degree of integration of the sub-pixels SP, the substrate SUB may be provided as a silicon substrate. The sub-pixels SP and/or the display panel DP may be formed on the substrate SUB as the silicon substrate. The display device 100 (see FIG. 1) including the display panel DP formed on the substrate SUB as the silicon substrate may be designated as an OLED on Silicon (OLEDoS) display device.

The sub-pixels SP may be in the display area DA on the substrate SUB. The sub-pixels SP may be arranged in a matrix form along a first direction DR1 and a second direction DR2 intersecting the first direction DR1. However, embodiments are not limited thereto. For example, the sub-pixels SP may be arranged in a zigzag form along the first direction DR1 and the second direction DR2. For example, the sub-pixels SP may be arranged in a PENTILE™ form or arrangement. The first direction DR1 may be a row direction, and the second direction DR2 may be a column direction.

Two or more sub-pixels among the sub-pixels SP may constitute one pixel PXL. For example, the pixel PXL may include two or more sub-pixels selected from among the sub-pixels SP.

A component for controlling the sub-pixels SP may be in the non-display area NDA on the substrate SUB. For example, lines connected to the sub-pixels SP, such as the first to mth gate lines GL1 to GLm and the first to nth data lines DL1 to DLn, which are shown in FIG. 1, may be in the non-display area NDA.

At least one of the gate driver 120, the data driver 130, the voltage generator 140, the controller 150, or the temperature sensor 160, which are shown in FIG. 1, may be integrated in the non-display area NDA of the display panel DP. In one or more embodiments, the gate driver 120 shown in FIG. 1 is mounted on the display panel DP, and may be in the non-display area NDA. In one or more embodiments, the gate driver 120 may be implemented as an integrated circuit distinguished from the display panel DP. In one or more embodiments, the temperature sensor 160 may be in the non-display area NDA and may be configured to sense a temperature of the display panel DP.

The pads PD may be in the non-display area NDA on the substrate SUB.

The pads PD may be electrically connected to the sub-pixels SP through the lines. For example, the pads PD may be connected to the sub-pixels SP through the first to nth data lines DL1 to DLn.

The pads PD may interface the display panel DP with other components of the display device 100 (see FIG. 1). In one or more embodiments, voltages and signals, which are necessary for operations of components included in the display panel DP, may be provided from the driver integrated circuit DIC shown in FIG. 1 through the pads PD. For example, the first to nth data lines DL1 to DLn may be connected to the driver integrated circuit DIC through the pads PD. For example, the first and second power voltages VDD and VSS may be received from the driver integrated circuit DIC through the pads PD. When the gate driver 120 is mounted in the display panel DP, the gate control signal GCS may be transmitted from the driver integrated circuit DIC to the gate driver 120 through the pads PD.

In one or more embodiments, a circuit board may be electrically connected to the pads PD, using a conductive adhesive member such as an anisotropic conductive film. The circuit board may be a Flexible Printed Circuit Board (FPCB) or a flexible film, which has a flexible material. The driver integrated circuit DIC may be mounted on the circuit board to be electrically connected to the pads PD.

In one or more embodiments, the display area DA may have one or more suitable shapes. The display area DA may have a closed-loop shape including linear sides and/or curved sides. For example, the display area DA may have shapes such as a polygon, a circle, a semicircle, and an ellipse.

In one or more embodiments, the display panel DP may have a flat display surface. In one or more embodiments, the display panel DP may have a round display surface or at least a partially round display surface. In one or more embodiments, the display panel DP may be bendable, foldable or rollable. The display panel DP and/or the substrate SUB may include materials having flexibility (e.g., flexible materials).

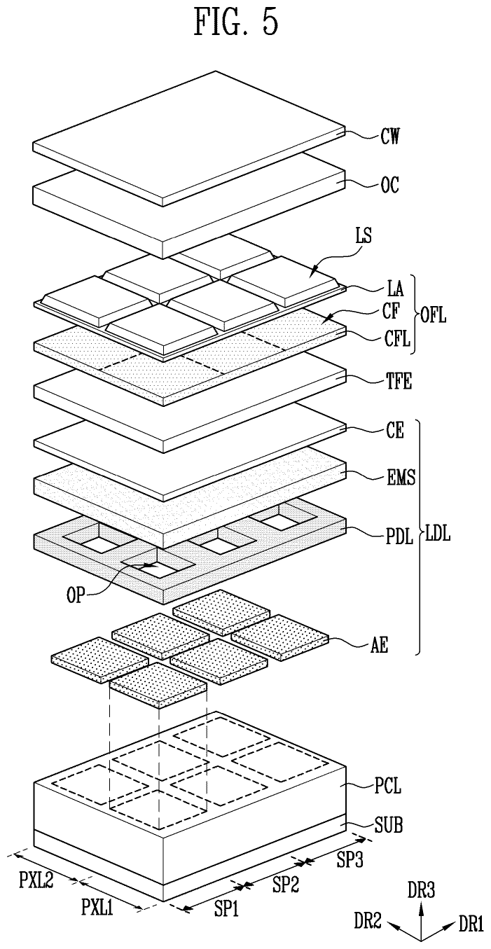

FIG. 5 is an exploded perspective view illustrating a portion of the display panel shown in FIG. 4. In FIG. 5, for clear and brief description, a portion of the display panel DP, which corresponds to two pixels PXL1 and PXL2 among the pixels PXL shown in FIG. 4, may be schematically illustrated. A portion of the display panel DP, which corresponds to the other pixels, may also be configured identically.

Referring to FIGS. 4 and 5, each of first and second pixels PXL1 and PXL2 may include first to third sub-pixels SP1 to SP3. However, embodiments are not limited thereto. For example, each of the first and second pixels PXL1 and PXL2 may include four sub-pixels or include two sub-pixels.

In FIG. 5, it may be illustrated that the first to third sub-pixels SP1 to SP3 may have quadrangular shapes when viewed in a third direction DR3 intersecting the first and second directions DR1 and DR2, and have the same size. However, embodiments are not limited thereto. The first to third sub-pixels SP1 to SP3 may be modified to have one or more suitable shapes.

The display panel DP may include a substrate SUB, a pixel circuit layer PCL, a light emitting element layer LDL, an encapsulation layer TFE, an optical functional layer OFL, an overcoat layer OC, and a cover window CW.

In one or more embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. In one or more embodiments, the substrate SUB may include a glass substrate. In one or more embodiments, the substrate SUB may include a polyimide (PI) substrate.

The pixel circuit layer PCL may be on the substrate SUB. The substrate SUB and/or the pixel circuit layer PCL may include insulating layers and conductive patterns between the insulating layers. The conductive patterns of the pixel circuit layer PCL may serve as at least some of circuit elements, lines, and the like. The conductive patterns may include copper, but embodiments are not limited thereto.

The circuit elements may include a sub-pixel circuit SPC (see FIG. 2) of each of the first to third sub-pixels SP1 to SP3. The sub-pixel circuit SPC may include transistors and one or more capacitors. Each transistor may include a semiconductor portion including a source region, a drain region, and a channel region, and a gate electrode overlapping with the semiconductor portion. In one or more embodiments, when the substrate SUB is provided as a silicon substrate, the semiconductor portion may be included in the substrate SUB, and the gate electrode may be included as a conductive pattern of the pixel circuit layer PCL in the pixel circuit layer PCL. In one or more embodiments, when the substrate SUB is provided as a glass substrate or a PI substrate, the semiconductor portion and the gate electrode may be included in the pixel circuit layer PCL. Each capacitor may include electrodes spaced and/or apart (e.g., spaced apart) from each other. For example, each capacitor may include electrodes spaced and/or apart (e.g., spaced apart) from each other on a plane defined by the first and second directions DR1 and DR2. For example, the capacitor may include electrodes spaced and/or apart (e.g., spaced apart) from each other in the third direction DR3 with an insulating layer interposed therebetween.

The lines of the pixel circuit layer PCL may include signal lines, e.g., a gate line, an emission control line, a data line, and the like, which are connected to each of the first to third sub-pixels SP1 to SP3. The lines may further include a line connected to the first power voltage node VDDN shown in FIG. 2. The lines may further include a line connected to the second power voltage node VSSN shown in FIG. 2.

The light emitting element layer LDL may include anode electrodes AE, a pixel defining layer PDL, a light emitting structure EMS, and a cathode electrode CE.

The anode electrodes AE may be on the pixel circuit layer PCL. The anode electrodes AE may be electrically connected to the circuit elements of the pixel circuit layer PCL. The anode electrodes AE may include an opaque conductive material capable of reflecting light, but embodiments are not limited thereto.

The pixel defining layer PDL may be over the anode electrodes AE. The pixel defining layer PDL may include an opening OP exposing a portion of each of the anode electrodes AE. The opening OP of the pixel defining layer PDL may be understood as an emission area corresponding to each of the first to third sub-pixels SP1 to SP3.

In one or more embodiments, the pixel defining layer PDL may include an inorganic material. The pixel defining layer PDL may include a plurality of stacked inorganic layers. For example, the pixel defining layer PDL may include silicon oxide (SiOx) and silicon nitride (SiNx). In one or more embodiments, the pixel defining layer PDL may include an organic material. However, the material of the pixel defining layer PDL is not limited thereto.

The light emitting structure EMS may be on the anode electrodes AE exposed by the openings OP of the pixel defining layer PDL. The light emitting structure EMS may include a light emitting layer configured to generate light, an electron transport layer configured to transport electrons, a hole transport layer configured to transport holes, and the like.

In one or more embodiments, the light emitting structure EMS fills the opening OP of the pixel defining layer PDL, and may be on (e.g., entirely on) the top of the pixel defining layer PDL. The light emitting structure EMS may be extended throughout the first to third sub-pixels SP1 to SP3. At least some of the layers in the light emitting structure EMS may be separated (cut) or bent at boundaries between the first to third sub-pixels SP1 to SP3. However, embodiments are not limited thereto. For example, portions of the light emitting structure EMS, which correspond to the first to third sub-pixels SP1 to SP3, may be separated from each other, and each of the separated light emitting structures EMS may be in the opening OP of the pixel defining layer PDL.

The cathode electrode CE may be on the light emitting structure EMS. The cathode electrode CE may be extended throughout the first to third sub-pixels SP1 to SP3. As such, the cathode electrode CE may be provided as a common electrode for the first to third sub-pixels SP1 to SP3.

The cathode electrode CE may be a thin metal layer having a thickness to a degree to which light emitted from the light emitting structure EMS can be transmitted therethrough. That is, the cathode electrode CE may have a thickness suitable for light emitted from the light emitting structure EMS to be transmitted therethrough. The cathode electrode CE may include (e.g., may be formed of) a metal material to have a relatively thin thickness or may include (e.g., may be formed of) a transparent conductive material. In one or more embodiments, the cathode electrode CE may include at least one of one or more suitable transparent conductive materials including indium tin oxide, indium zinc oxide, indium tin zinc oxide, aluminum zinc oxide, gallium zinc oxide, zinc tin oxide, or gallium tin oxide. In one or more embodiments, the cathode electrode CE may include at least one of silver (Ag), magnesium (Mg), or mixtures thereof. However, the material of the cathode electrode CE is not limited thereto.

It may be understood that any one of the anode electrodes AE, a portion of the light emitting structure EMS, which overlaps therewith, and a portion of the cathode electrode CE, which overlaps therewith, constitute one light emitting element LD (see FIG. 2). Each of light emitting elements of the first to third sub-pixels SP1 to SP3 may include one anode electrode AE, a portion of the light emitting structure EMS, which overlaps therewith, and a portion of the cathode electrode CE, which overlaps therewith. In each of the first to third sub-pixels SP1 to SP3, holes injected from the anode electrode AE and electrons injected from the cathode electrode CE may be transported into a light emitting layer of the light emitting structure EMS to form excitons, and light may be generated when the excitons are changed from an excited state to a ground state. A luminance of the light may be determined according to an amount of current flowing through the light emitting layer. A wavelength band of the generated light may be determined according to a configuration of the light emitting layer.

The encapsulation layer TFE may be over the cathode electrode CE. The encapsulation layer TFE may cover the light emitting element layer LDL and/or the pixel circuit layer PCL. The encapsulation layer TFE may be configured to prevent oxygen and/or moisture from infiltrating into the light emitting element layer LDL. In one or more embodiments, the encapsulation layer TFE may include a structure in which at least one inorganic layer and at least one organic layer are alternately stacked. For example, the inorganic layer may include silicon nitride, silicon oxide, silicon oxynitride (SiOxNy), or the like. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB). However, the materials of the organic layer and the inorganic layer of the encapsulation layer TFE are not limited thereto.

In order to improve encapsulation efficiency of the encapsulation layer TFE, the encapsulation layer TFE may further include a thin film including aluminum oxide (AlOx). The thin film including the aluminum oxide may be located on a top surface of the encapsulation layer TFE, which faces the optical functional layer OFL, and/or a bottom surface of the encapsulation layer TFE, which faces the light emitting element layer LDL.

The thin film including the aluminum oxide may be formed through an Atomic Layer Deposition (ALD) process. However, embodiments are not limited thereto. The encapsulation layer TFE may further include a thin film formed of at least one of one or more materials suitable for the improvement of the encapsulation efficiency.

The optical functional layer OFL may be on the encapsulation layer TFE. The optical functional layer OFL may include a color filter layer CFL and a lens array LA.

The color filter layer CFL may be between the encapsulation layer TFE and the lens array LA. The color filter layer CFL may be configured to filter light emitted from the light emitting structure EMS, thereby selectively outputting light of a wavelength band or a color, which corresponds to each sub-pixel. The color filter layer CFL may include color filters CF respectively corresponding to the first to third sub-pixels SP1 to SP3. Each of the color filters CF may allow light having a wavelength band corresponding to a corresponding sub-pixel to pass therethrough. For example, a color filter corresponding to the first sub-pixel SP1 may allow light of a red color to pass therethrough, a color filter corresponding to the second sub-pixel SP2 may allow light of a green color to pass therethrough, and a color filter corresponding to the third sub-pixel SP3 may allow light of a blue color to pass therethrough. According to light emitted from the light emitting structure EMS in each sub-pixel SP, at least some of the color filters CF may not be provided.

The lens array LA may be on the color filter layer CFL. The lens array LA may include lenses LS respectively corresponding to the first to third sub-pixels SP1 to SP3. Each of the lenses LS may be configured to output light emitted from the light emitting structure EMS along an intended path, thereby improving light emission efficiency. The lens array LA may have a relatively high refractive index. For example, the lens array LA may have a refractive index higher than a refractive index of the overcoat layer OC. In one or more embodiments, the lenses LS may include an organic material. In one or more embodiments, the lenses LS may include an acryl-based material. However, the material of the lenses LS is not limited thereto.

In one or more embodiments, as compared with the opening OP of the pixel defining layer PDL, at least some of the color filters CF of the color filter layer CFL and at least some of the lenses LS of the lens array LS may be shifted in a direction parallel to a plane defined by the first and second directions DR1 and DR2. In one or more embodiments, in a central area of the display area DA, the center of a color filter and the center of a lens may be aligned or overlap with the center of a corresponding opening OP of the pixel defining layer PDL. For example, in the central area of the display area DA, the opening OP of the pixel defining layer PDL may completely overlap with the corresponding color filter of the color filter layer CFL and the corresponding lens of the lens array LA. In an area of the display area DA, which is adjacent to the non-display area NDA, the center of a color filter and the center of a lens may be shifted in a planar direction from the center of an opening OP of the pixel defining layer PDL. For example, in the area of the display area DA, which is adjacent to the non-display area NDA, the opening OP of the pixel defining layer PDL may partially overlap with the corresponding color filter of the color filter layer CFL and the corresponding lens of the lens array LA. Accordingly, in the center of the display area DA, light emitted from the light emitting structure EMS can be effectively output in a normal direction of the display surface. At an outer portion of the display area DA, light emitted from the light emitting structure EMS can be effectively output in a direction inclined by an angle (e.g., a set or predetermined angle) with respect to the normal direction of the display surface.

The overcoat layer OC may be over the lens array LA. The overcoat layer OC may cover the optical functional layer OFL, the encapsulation layer TFE, the light emitting structure EMS, and/or the pixel circuit layer PCL. The overcoat layer OC may include one or more materials suitable for protecting lower layers thereof from foreign matters such as dust and moisture. For example, the overcoat layer OC may include at least one of an inorganic insulating layer or an organic insulating layer. For example, the overcoat layer OC may include epoxy, but embodiments are not limited thereto. The overcoat layer OC may have a refractive index lower than a refractive index of the lens array LA.

The cover window CW may be on the overcoat layer OC. The cover window CW may be configured to protect lower layers thereof or thereunder. The cover window CW may have a refractive index higher than the refractive index of the overcoat layer OC. The cover window CW may include glass, but embodiments are not limited thereto. For example, the cover window CW may be an encapsulation glass configured to protect components thereunder. In one or more embodiments, the cover window CW may not be provided.

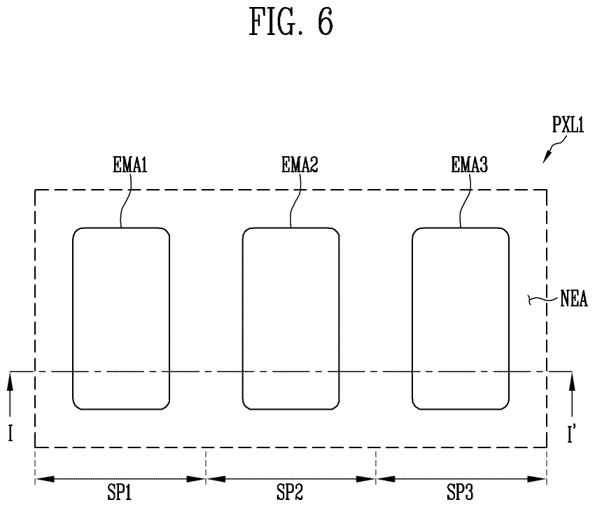

FIG. 6 is a plan view illustrating further details of any one of the pixels shown in FIG. 5 according to some embodiments. In FIG. 6, for clear and brief description, the first pixel PXL1 among the first and second pixels PXL1 and PXL2 shown in FIG. 5 is schematically illustrated. The other pixels may be configured identically to the first pixel PXL1.

Referring to FIGS. 5 and 6, the first pixel PXL1 may include first to third sub-pixels SP1 to SP3 arranged in the first direction DR1.

The first sub-pixel SP1 may include a first emission area EMA1 and a non-emission area NEA at the periphery of the first emission area EMA1. The second sub-pixel SP2 may include a second emission area EMA2 and the non-emission area NEA at the periphery of the second emission area EMA2. The third sub-pixel SP3 may include a third emission area EMA3 and the non-emission area NEA at the periphery of the third emission area EMA3.

The first emission area EMA1 may be an area in which light is emitted from a portion of the light emitting structure EMS (see FIG. 5), which corresponds to the first sub-pixel SP1. The second emission area EMA2 may be an area in which light is emitted from a portion of the light emitting structure EMS, which corresponds to the second sub-pixel SP2. The third emission area EMA3 may be an area in which light is emitted from a portion of the light emitting structure EMS, which corresponds to the third sub-pixel SP3. As described with reference to FIG. 5, each emission area may be understood as openings OP of the pixel defining layer PDL, which respectively correspond to the first to third sub-pixels SP1 to SP3.

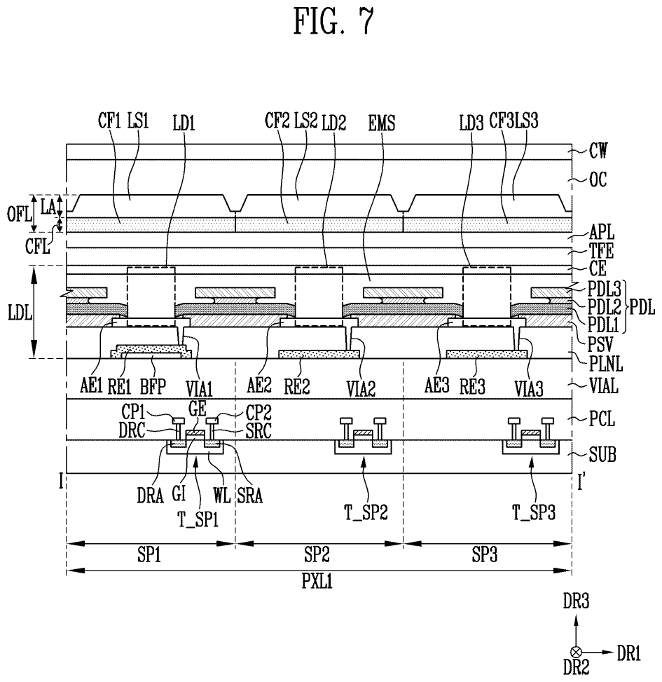

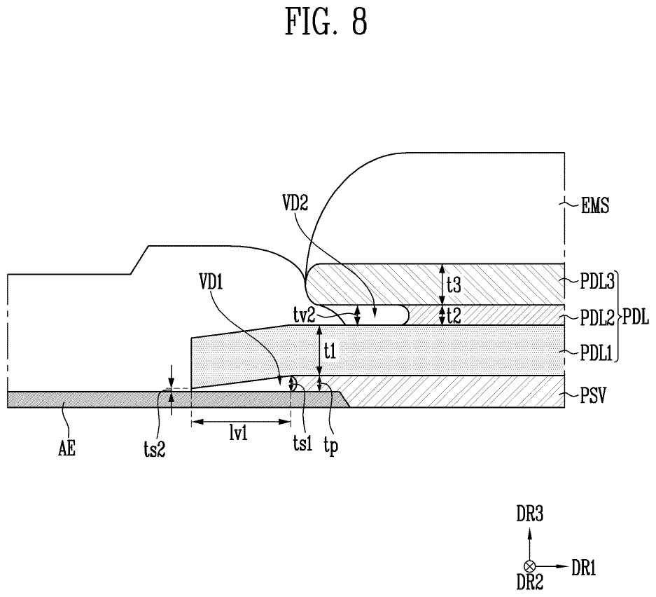

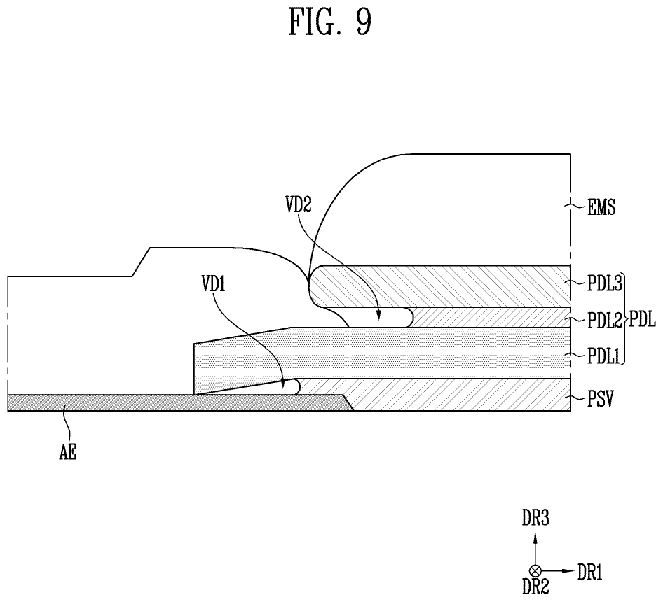

FIG. 7 is a cross-sectional view taken along the line I-I′ shown in FIG. 6. FIGS. 8 and 9 are cross-sectional views illustrating aspects of a protective layer and a pixel defining layer, which are shown in FIG. 7.

Referring to FIG. 7, a pixel circuit layer PCL may be provided on a substrate SUB. The substrate SUB may include a silicon wafer substrate formed using a semiconductor process. For example, the substrate SUB may include silicon, germanium, and/or silicon-germanium.

The pixel circuit layer PCL may be on the substrate SUB. The substrate SUB and the pixel circuit layer PCL may include circuit elements of each of first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of transistors included in a sub-pixel circuit SPC (see FIG. 2) of the first sub-pixel SP1, the transistor T_SP2 of the second sub-pixel SP2 may be any one of transistors included in a sub-pixel circuit SPC of the second sub-pixel SP2, and the transistor T_SP3 of the third sub-pixel SP3 may be any one of transistors included in a sub-pixel circuit SPC of the third sub-pixel SP3. In FIG. 7, for a clearer and briefer description, one of the transistors of each sub-pixel is illustrated, and the other circuit elements are not provided.

The transistors T_SP1 of the first sub-pixel SP1 may include a source region SRA, a drain region DRA, and a gate electrode GE.

The source region SRA and the drain region DRA may be in the substrate SUB. A well WL formed through an ion implantation process may be in the substrate SUB, and the source region SRA and the drain region DRA may be in the well WL to be spaced and/or apart (e.g., spaced apart) from each other. A region between the source region SRA and the drain region DRA in the well WL may be defined as a channel region.

The gate electrode GE may overlap with the channel region between the source region SRA and the drain region DRA, and be in the pixel circuit layer PCL. The gate electrode GE may be spaced and/or apart (e.g., spaced apart) from the well WL or the channel region by an insulating material such as a gate insulating layer Gl. The gate electrode GE may include a conductive material.

A plurality of layers included in the pixel circuit layer PCL may include insulating layers and conductive patterns located between the insulating layers, and the conductive patterns may include first and second conductive patterns CP1 and CP2. The first conductive pattern CP1 may be electrically connected to the drain region DRA through a drain connection portion DRC penetrating one or more insulating layers. The second conductive pattern CP2 may be electrically connected to the source region SRA through a source connection portion SRC penetrating one or more insulating layers.

As the gate electrode GE and the first and second conductive patterns CP1 and CP2 are connected to other circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be configured identically or nearly identically to the transistor T_SP1 of the first sub-pixel SP1.

As such, the substrate SUB and/or the pixel circuit layer PCL may include circuit elements of each of the first to third sub-pixels SP1 to SP3.

A via layer VIAL may be on the pixel circuit layer PCL. The via layer VIAL covers the pixel circuit layer PCL, and may have a flat (e.g., an entirely flat) surface. The via layer VIAL may be configured to planarize step differences on the pixel circuit layer PCL. The via layer VIAL may include at least one of silicon oxide (SiOx), silicon nitride (SiNx), or silicon carbon nitride (SiCN), but embodiments are not limited thereto.

A light emitting element layer LDL may be on the via layer VIAL. The light emitting element layer LDL may include first to third reflective electrodes RE1, RE2, and RE3, a planarization layer PLNL, first to third anode electrodes AE1, AE2, and AE3, a pixel defining layer PDL, a light emitting structure EMS, and a cathode electrode CE.

On the via layer VIAL, the first to third reflective electrodes RE1 to RE3 may be in the first to third sub-pixels SP1 to SP3, respectively. For example, the first to third reflective electrodes RE1 to RE3 each may be on the via layer VIAL. Each of the first to third reflective electrodes RE1 to RE3 may be connected to a circuit element in the pixel circuit layer PCL through a via penetrating the via layer VIAL.

The first to third reflective electrodes RE1 to RE3 may serve as full mirrors which reflect light emitted from the light emitting structure EMS toward a display surface (or a cover window CW). The first to third reflective electrodes RE1 to RE3 may include a metal material suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), or alloys of two or more materials selected therefrom, but embodiments are not limited thereto.

In one or more embodiments, a connection electrode may be under each of the first to third reflective electrodes RE1 to RE3. The connection electrode may improve an electrical connection characteristic between a corresponding reflective electrode and a circuit element of the pixel circuit layer PCL. The connection electrode may have a multi-layer structure. The multi-layer structure may include titanium (Ti), titanium nitride (TiN), tantalum nitride (TaN), and the like, but embodiments are not limited thereto. In one or more embodiments, a corresponding reflective electrode may be located between multiple layers of the connection electrode.

A buffer pattern BFP may be under at least one of the first to third reflective electrodes RE1 to RE3. The buffer pattern BFP may include an inorganic material such as silicon carbon nitride, but embodiments are not limited thereto. As the buffer pattern BFP is arranged under at least one of the first to third reflective electrodes RE1 to RE3, a height of the corresponding reflective electrode in a third direction DR3 may be controlled. For example, the buffer pattern BFP may be between the first reflective electrode RE1 and the via layer VIAL, to control a height of the first reflective electrode RE1.

The first to third reflective electrodes RE1 to RE3 may serve as full mirrors, and the cathode electrode CE may serve as a half mirror. Light emitted from a light emitting layer of the light emitting structure EMS may be amplified by at least partially reciprocating between a corresponding reflective electrode and the cathode electrode CE, and the amplified light may be outputted through the cathode electrode CE. As such, a distance between each reflective electrode and the cathode electrode CE may be understood as a resonance distance of light emitted from the light emitting layer of the corresponding light emitting structure EMS.

By the buffer pattern BFP, the first sub-pixel SP1 may have a resonance distance shorter than a resonance distance of another sub-pixel. Light in a specific wavelength range (e.g., a red color) may be effectively and efficiently amplified by the adjusted resonance distance. Accordingly, the first sub-pixel SP1 can effectively and efficiently output light of the corresponding wavelength range.

In FIG. 7, it is illustrated the buffer pattern BFP is provided to the first sub-pixel SP1 and is not provided to the second and third sub-pixels SP2 and SP3. That is, FIG. 7 illustrates the first sub-pixel SP1 as including a buffer pattern BFP and the second and third sub-pixels SP2 and SP3 as not including a buffer pattern BFP. However, embodiments are not limited thereto. The buffer pattern may be provided in at least one of the second sub-pixel SP2 or the third sub-pixel SP3, and may be configured to adjust a resonance distance of the at least one of the second sub-pixel SP2 or the third sub-pixel SP3. For example, the first to third sub-pixels SP1 to SP3 may respectively correspond to red, green, and blue. A distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

The planarization layer PLNL may be on the via layer VIAL and the first to third reflective electrodes RE1 to RE3 to planarize step differences between the first to third reflective electrodes RE1 to RE3. The planarization layer PLNL covers (e.g., entirely covers) the first to third reflective electrodes RE1 to RE3 and the via layer VIAL, and may have a flat surface. In one or more embodiments, the planarization layer PLNL may not be provided.

The first to third anode electrodes AE1 to AE3 respectively overlapping with the first to third reflective electrodes RE1 to RE3 may be on the planarization layer PLNL. The first to third anode electrodes AE1 to AE3 may have shapes similar to the shapes of the first to third emission area EMA1 to EMA3 shown in FIG. 6 when viewed in the third direction DR3 (e.g., in a plan view). The first to third anode electrodes AE1 to AE3 may be electrically connected to the first to third reflective electrodes RE1 to RE3, respectively. The first anode electrode AE1 may be electrically connected to the first reflective electrode RE1 through a first via VIA1 penetrating the planarization layer PLNL. The second anode electrode AE2 may be electrically connected to the second reflective electrode RE2 through a second via VIA2 penetrating the planarization layer PLNL. The third anode electrode AE3 may be electrically connected to the third reflective electrode RE3 through a third via VIA3 penetrating the planarization layer PLNL.

In one or more embodiments, the first to third anode electrodes AE1 to AE3 may include at least one of transparent conductive materials such as indium tin oxide (ITO), indium zinc oxide (IZO), zinc oxide (ZnOx), indium gallium zinc oxide (IGZO), or indium tin zinc oxide (ITZO), but embodiments are not limited thereto. However, the material of the first to third anode electrodes AE1 to AE3 is not limited thereto. For example, the first to third anode electrodes AE1 to AE3 may include titanium nitride.

In one or more embodiments, insulating layers for adjusting a height of at least one of the first to third anode electrodes AE1 to AE3 may be further included. The insulating layers may be between at least one of the first to third anode electrodes AE1 to AE3 and corresponding reflective electrodes. The planarization layer PLNL and/or the buffer pattern BFP may not be provided. For example, the first to third sub-pixels SP1 to SP3 may correspond to red, green, and blue, respectively, a distance between the first anode electrode AE1 and the cathode electrode CE may be shorter than a distance between the second anode electrode AE2 and the cathode electrode CE, and the distance between the second anode electrode AE2 and the cathode electrode CE may be shorter than a distance between the third anode electrode AE3 and the cathode electrode CE.

As shown in FIGS. 8 and 9, a protective layer PSV may be on an anode electrode AE. The protective layer PSV may be on (e.g., directly on) the anode electrode AE. The protective layer PSV may be configured to prevent or reduce damage to the anode electrode AE in a process of forming the pixel defining layer PDL by covering the anode electrode AE. The protective layer PSV may include an opening exposing a portion of each of the first to third anode electrodes AE1 to AE3. The protective layer PSV may include aluminum or an aluminum alloy, but the present disclosure is not necessarily limited thereto.

The pixel defining layer PDL may be on the protective layer PSV. The pixel defining layer PDL may include an opening exposing a portion of each of the first to third anode electrodes AE1 to AE3. The opening of the pixel defining layer PDL may define an emission area of each of the first to third anode electrodes AE1 to AE3. As such, the pixel defining layer PDL may be in the non-emission area NEA shown in FIG. 6 to define the first to third emission areas EMA1 to EMA3 shown in FIG. 6.

The pixel defining layer PDL may include first to third pixel defining layers PDL1, PDL2, and PDL3. Each of the first to third pixel defining layers PDL1, PDL2, and PDL3 may include at least one of silicon oxide (SiOx) or silicon nitride (SiNx), but embodiments according to the present disclosure are not necessarily limited thereto.

The first pixel defining layer PDL1 may be on the anode electrode AE and the protective layer PSV. The first pixel defining layer PDL1 may be on (e.g., directly on) the protective layer PSV. A first void VD1 may be formed between the anode electrode AE and the first pixel defining layer PDL1. For example, a bottom surface of the first void VD1 may be defined by the anode electrode AE. A top surface of the first void VD1 may be defined by the first pixel defining layer PDL1. A first side of the first void VD1 may be defined by the protective layer PSV. A second side of the first void VD1 may be defined by the light emitting structure EMS.

A width of the first pixel defining layer PDL1 in the first direction DR1 may be greater than a width of the protective layer PSV in the first direction DR1. A width of the opening of the first pixel defining layer PDL1 in the first direction DR1 may be smaller than a width of the opening of the protective layer PSV in the first direction DR1. A thickness t1 of the first pixel defining layer PDL1 in the third direction DR3 may be greater than a thickness tp of the protective layer PSV in the third direction DR3, but the present disclosure is not necessarily limited thereto. The thickness tp of the protective layer PSV in the third direction DR3 means a distance from a top surface of the anode electrode AE to a top surface of the protective layer PSV in the third direction DR3.

In one or more embodiments, the first pixel defining layer PDL1 may have a shape in which an edge thereof lands on the anode electrode AE. The edge of the first pixel defining layer PDL may land on the anode electrode AE in a process of forming the opening of the protective layer PSV. Accordingly, one area of the first pixel defining layer PDL1, which overlaps with the opening of the protective layer PSV in the third direction DR3, may have a slope on the anode electrode AE. That is, the one area of the first pixel defining layer PDL1, which protrudes from the protective layer PSV, may partially have a slope on the anode electrode AE. As such, when the edge of the first pixel defining layer PDL1 lands on the anode electrode AE, a distance between the edge of the first pixel defining layer PDL1 and the anode electrode AE can be minimized or reduced. Accordingly, the light emitting structure EMS and/or the cathode electrode CE can be prevented from being disconnected by an undercut structure of the protective layer PSV.

In order for the edge of the first pixel defining layer PDL1 to be more easily arranged, a width Iv1 of the first pixel defining layer PDL1 protruding from the protective layer PSV in the first direction DR1 (or a width of the first void VD1 in the first direction DR1) may be greater than the thickness tp of the protective layer PSV in the third direction DR3. However, the width Iv1 of the first pixel defining layer PDL1 protruding from the protective layer PSV in the first direction DR1 (or the width of the first void VD1 in the first direction DR1) is not necessarily limited thereto, and may be variously changed within a range in which the edge of the first pixel defining layer PDL1 can be more easily arranged.

As shown in FIG. 8, the edge of the first pixel defining layer PDL1 may be spaced and/or apart (e.g., spaced apart) from the anode electrode AE in the third direction DR3. In order to prevent or reduce instances of the disconnection caused by the undercut structure, a distance between the edge of the first pixel defining layer PDL1 and the anode electrode AE in the third direction DR3 may be formed as 200 Å or less. In one or more embodiments, as shown in FIG. 9, the edge of the first pixel defining layer PDL1 may be in contact with the anode electrode AE. As such, when the edge of the first pixel defining layer PDL1 is arranged (e.g., completely arranged) to be in contact (e.g., direct contact) with the anode electrode AE, the disconnection caused by the undercut structure can be more effectively prevented or reduced.

As described above, when the one area of the first pixel defining layer PDL, which protrudes from the protective layer PSV, has a slope on the anode electrode AE, the top surface of the first void VD1 may have a slope. A thickness ts1 of the first side of the first void VD1 in the third direction DR3 may be greater than a thickness ts2 of the second side of the first void VD1 in the third direction DR3. The thickness ts1 of the first side of the first void VD1 in the third direction DR3 may be equal to the thickness tp of the protective layer PSV in the third direction DR3.

The second pixel defining layer PDL2 may be on the first pixel defining layer PDL1. The second pixel defining layer PDL2 may be on (e.g., directly on) the first pixel defining layer PDL1. A width of the second pixel defining layer PDL2 in the first direction DR1 may be smaller than the width of the first pixel defining layer PDL1 in the first direction DR1. A width of an opening of the second pixel defining layer PDL2 in the first direction DR1 may be greater than the width of the opening of the first pixel defining layer PDL1 in the first direction DR1. A thickness t2 of the second pixel defining layer PDL2 in the third direction DR3 may be smaller than the thickness t1 of the first pixel defining layer PDL1 in the third direction DR3. The thickness t2 of the second pixel defining layer PDL2 in the third direction DR3 may be greater than the thickness tp of the protective layer PSV in the third direction DR3, but the present disclosure is not necessarily limited thereto.

The third pixel defining layer PDL3 may be on the second pixel defining layer PDL2. The third pixel defining layer PDL3 may be on (e.g., directly on) the second pixel defining layer PDL2. A width of the third pixel defining layer PDL3 in the first direction DR1 may be greater than the width of the second pixel defining layer PDL in the first direction DR1. The width of the third pixel defining layer PDL3 in the first direction DR1 may be smaller than the width of the first pixel defining layer PDL1 in the first direction DR1, but the present disclosure is not necessarily limited thereto. A width of an opening of the third pixel defining layer PDL3 in the first direction DR1 may be greater than the width of the opening of the first pixel defining layer PDL1 in the first direction DR1. A thickness t3 of the third pixel defining layer PDL3 in the third direction DR3 may be greater than the thickness t2 of the second pixel defining layer PDL2 in the third direction DR3, but the present disclosure is not necessarily limited thereto.

A second void VD2 may be formed between the first pixel defining layer PDL1 and the third pixel defining layer PDL3. For example, a bottom surface of the second void VD2 may be defined by the first pixel defining layer PDL1. A top surface of the second void VD2 may be defined by the third pixel defining layer PDL3. A first side of the second void VD2 may be defined by the second pixel defining layer PDL2. A second side of the second void VD2 may be defined by the light emitting structure EMS. A thickness tv2 of the second void VD2 in the third direction DR3 may be greater than the thickness of ts1 of the first side of the first void VD1 in the third direction DR3, but the present disclosure is not necessarily limited thereto.

The second void VD2 may cause a discontinuity to be formed in the light emitting structure EMS between the first to third sub-pixels SP1 to SP3. Some of a plurality of layers stacked in the light emitting structure EMS may be cut or bent by the second void VD2. For example, at least one charge generation layer included in the light emitting structure EMS may be cut in the second void VD2. As such, portions of the light emitting structure EMS included in the first to third sub-pixels SP1 to SP3 may be at least partially separated from each other due to the second void VD2. Accordingly, in an operation of the display panel DP, a current leaked from each of the first to third sub-pixels SP1 to SP3 to a sub-pixel adjacent thereto through layers included in the light emitting structure EMS can be decreased. Thus, first to third light emitting elements LD1 to LD3 can operate with relatively high reliability.

The light emitting structure EMS may be on the anode electrode AE and the pixel defining layer PDL. The light emitting structure EMS may be on anode electrodes AE exposed by the protective layer and the pixel defining layer PDL. The light emitting structure EMS may be arranged (e.g., entirely arranged) throughout the first to third sub-pixels SP1 to SP3. The light emitting structure EMS may have a structure in which a plurality of layers are stacked.

Some or all of the plurality of layers included in the light emitting structure EMS may be separated or bent by the second void VD2 between the first to third sub-pixels SP1 to SP3.

The cathode electrode CE may be on the light emitting structure EMS. The cathode electrode CE may be commonly provided in the first to third sub-pixels SP1 to SP3. The cathode electrode CE may serve as a half mirror which may allow light emitted from the light emitting structure EMS to be partially transmitted therethrough and to be partially reflected therefrom.

The cathode electrode CE may be commonly provided in the first to third sub-pixels SP1 to SP3.

The first anode electrode AE1, a portion of the light emitting structure EMS, which overlaps with the first anode electrode AE1, and a portion of the cathode electrode CE, which overlaps with the first anode electrode AE1, may constitute the first light emitting element LD1. That is, the first light emitting element LD1 may include the first anode electrode AE1, a portion of the light emitting structure EMS overlapping the first anode electrode AE1, and a portion of the cathode electrode CE overlapping the first anode electrode AE1. The second anode electrode AE2, a portion of the light emitting structure EMS, which overlaps with the second anode electrode AE2, and a portion of the cathode electrode CE, which overlaps with the second anode electrode AE2, may constitute the second light emitting element LD2. That is, the second light emitting element LD2 may include the second anode electrode AE2, a portion of the light emitting structure EMS overlapping the second anode electrode AE2, and a portion of the cathode electrode CE overlapping the second anode electrode AE2 The third anode electrode AE3, a portion of the light emitting structure EMS, which overlaps with the third anode electrode AE3, and a portion of the cathode electrode CE, which overlaps with the third anode electrode AE3, may constitute the third light emitting element LD3. That is, the third light emitting element LD2 may include the third anode electrode AE3, a portion of the light emitting structure EMS overlapping the third anode electrode AE3, and a portion of the cathode electrode CE overlapping the third anode electrode AE3

An encapsulation layer TFE may be on the cathode electrode CE. The encapsulation layer TFE may prevent or reduce instances of contaminants such as oxygen and/or moisture infiltrating into the light emitting element layer LDL.

An optical functional layer OFL may be on the encapsulation layer TFE. In one or more embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting lower layers including the encapsulation layer TFE.

The optical functional layer OFL may include a color filter layer CFL and a lens array LA. The color filter layer CFL may include first to third color filters CF1 to CF3 respectively corresponding to the first to third sub-pixels SP1 to SP3. The first to third color filters CF1 to CF3 may allow lights having different wavelength ranges to pass therethrough. For example, the first to third color filters CF1 to CF3 may allow light red, green, and blue colors to pass therethrough, respectively.

In one or more embodiments, the first to third color filters CF1 to CF3 may partially overlap with each other between the first to third sub-pixels SP1 to SP3. In one or more embodiments, the first to third color filters CF1 to CF3 may be spaced and/or apart (e.g., spaced apart) from each other, and a black matrix may be provided between the first to third color filters CF1 to CF3.

The lens array LA may be on the color filter layer CFL. The lens array LA may include first to third lenses LS1 to LS3 respectively corresponding to the first to third sub-pixels SP1 to SP3. The first to third lenses LS1 to LS3 may respectively output lights emitted from the first to third light emitting layers LD1 to LD3 along intended paths, thereby improving light emission efficiency.

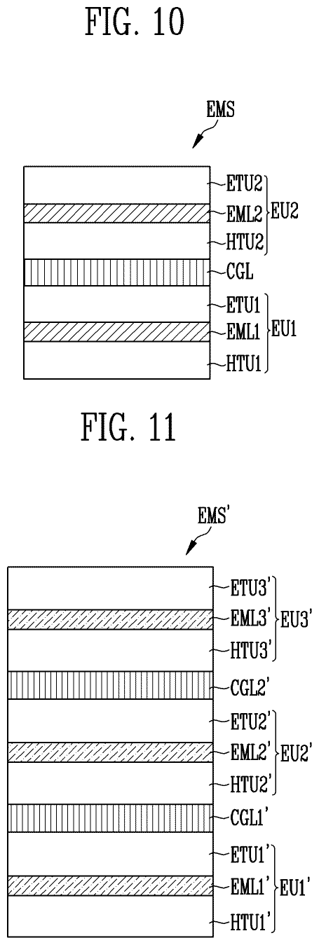

FIG. 10 is a cross-sectional view illustrating aspects of a light emitting structure included in any one of the first to third light emitting elements shown in FIG. 7 according to some embodiments.

Referring to FIG. 10, the light emitting structure EMS may have a tandem structure in which first and second light emitting units EU1 and EU2 are stacked. The light emitting structure EMS may be configured identically (e.g., substantially identically or nearly identically) in each of the first to third light emitting elements LD1, LD2, and LD3 shown in FIG. 7.

Each of the first and second light emitting units EU1 and EU2 may include at least one light emitting layer configured to generate light according to an applied current. The first light emitting unit EU1 may include a first light emitting layer EML1, a first electron transport unit ETU1, and a first hole transport unit HTU1. The first light emitting layer EML1 may be between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be between the second electron transport unit ETU2 and the second hole transport unit HTU2.

Each of the first and second hole transport units HTU1 and HTU2 may include at least one of a hole injection layer or a hole transport layer. Each of the first and second hole transport units HTU1 and HTU2 may further include a hole buffer layer, an electron blocking layer, and the like, if necessary or desired. The first and second hole transport units HTU1 and HTU2 may have the same configuration or have different configurations.

Each of the first and second electron transport units ETU1 and ETU2 may include at least one of an electron injection layer or an electron transport layer. Each of the first and second electron transport units ETU1 and ETU2 may further include an electron buffer layer, a hole blocking layer, and the like, if necessary or desired. The first and second electron transport units ETU1 and ETU2 may have the same configuration or have different configurations.

A connection layer, which may be provided in the form of a charge generation layer CGL, may be between the first light emitting unit EU1 and the second light emitting unit EU2 to connect the first light emitting unit EU1 and the second light emitting unit EU2 to each other. In one or more embodiments, the charge generation layer CGL may have a stacked structure of a p-dopant layer and an n-dopant layer. For example, the p-dopant layer may include a p-type dopant such as HAT-CN, TCNQ or NDP-9, and the n-dopant layer may include an alkali metal, an alkali earth metal, a lanthanide-based metal, or any combination thereof. However, embodiments are not limited thereto.

In one or more embodiments, the first light emitting layer EML1 and the second light emitting layer EML2 may be configured to generate lights of different colors. Lights respectively emitted from the first light emitting layer EML1 and the second light emitting layer EML2 may be mixed together to be viewed as white light. For example, the first light emitting layer EML1 may be configured to generate light of a blue color, and the second light emitting layer EML2 may be configured to generate light of a yellow color. In one or more embodiments, the second light emitting layer EML2 may include a structure in which a first sub-light emitting layer configured to generate light of a red color and a second sub-light emitting layer configured to generate light of a green color are stacked. The light of the red color and the light of the green color may be mixed together to provide the light of the yellow color. An intermediate layer configured to perform a function of transporting holes and/or a function of blocking transportation of electrodes may be further between the first and second sub-light emitting layers. In one or more embodiments, the first light emitting layer EML1 and the second light emitting layer EML2 may be configured to generate light of the same color.

The light emitting structure EMS may be formed through a process such as vacuum deposition or inkjet printing, but embodiments are not limited thereto.

FIG. 11 is a cross-sectional view illustrating aspects of the light emitting structure included in the one of the first to third light emitting elements shown in FIG. 7 according to some embodiments.

Referring to FIG. 11, a light emitting structure EMS' may a tandem structure in which first to third light emitting units EU1′ to EU3′ are stacked. The light emitting structure EMS' may be configured identically (e.g., substantially identically or nearly identically) in each of the first to third light emitting elements LD1 to LD3 shown in FIG. 7.

Each of the first to third light emitting units EU1′ to EU3′ may include a light emitting layer configured to generate light according to an applied current. The first light emitting unit EU1′ may include a first light emitting layer EML1′, a first electron transport unit ETU1′ and a first hole transport unit HTU1′. The first light emitting layer EML1′ may be between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be between the third electron transport unit ETU3′ and the third hole transport unit HTU3′.

Each of the first to third hole transport units HTU1′ to HTU3′ may include at least one of a hole injection layer or a hole transport layer, and further include a hole buffer layer, and an electron blocking layer, and the like, if necessary or desired. The first to third hole transport units HTU1′ to HTU3′ may have the same configuration or have different configurations.

Each of the first to third electron transport units ETU1′ to ETU3′ may include at least one of an electron injection layer or an electron transport layer, and further include an electron buffer layer, a hole blocking layer, and the like, if necessary or desired. The first to third electron transport units ETU1′ to ETU3′ may have the same configuration or have different configurations.

A first charge generation layer CGL1′ may be between the first light emitting unit EU1′ and the second light emitting unit EU2′. A second charge generation layer CGL2′ may be between the second light emitting unit EU2′ and the third light emitting unit EU3′.

In one or more embodiments, the first to third light emitting layers EML1′ to EML3′ may be configured to generate lights of different colors. Lights respectively emitted from the first to third light emitting layers EML1′ to EML3′ may be mixed together to be viewed as white light. For example, the first light emitting layer EML1′ may be configured to generate light of a blue color, the second light emitting layer EML2′ may be configured to generate light of a green color, and the third light emitting layer EML3′ may be configured to generate light of a red color. In one or more embodiments, at least two light emitting layers among the first to third light emitting layers EML1′ to EML3′ may be configured to generate light of the same color.

Unlike as shown in FIGS. 10 and 11, the light emitting structure EMS shown in FIG. 7 may include one light emitting unit in each of the first to third light emitting elements LD1 to LD3. The light emitting unit included in each of the first to third light emitting elements LD1 to LD3 may be configured to emit lights of different colors. For example, the light emitting unit of the first light emitting element LD1 may be configured to emit light of a red color, the light emitting unit of the second light emitting element LD2 may be configured to emit light of a green color, and the light emitting unit of the third light emitting element LD3 may be configured to emit light of a blue color. Light emitting units of the first to third sub-pixels SP1 to SP3 may be separated from each other, and each of the light emitting units may be in the opening OP of the pixel defining layer PDL. At least some of the color filters CF1 to CF3 may not be provided.

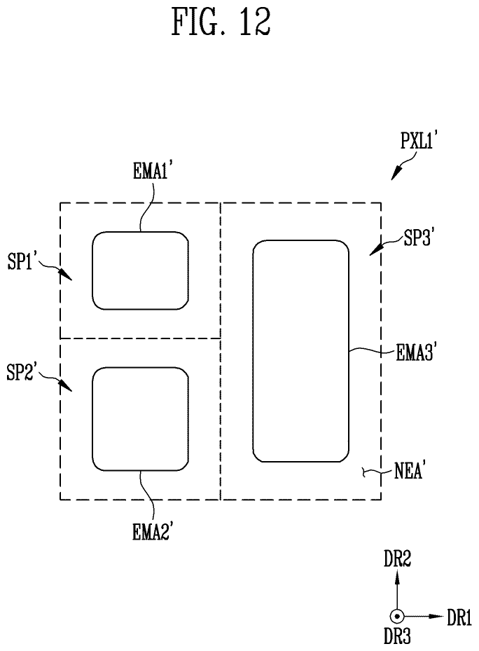

FIG. 12 is a plan view illustrating aspects of the one of the pixels shown in FIG. 5 according to some embodiments.

Referring to FIG. 12, a first pixel PXL1′ may include first to third sub-pixels SP1′ to SP3′.

The first sub-pixel SP1′ may include a first emission area EMA1′ and a non-emission area NEA′ at the periphery of the first emission area EMA1′. The second sub-pixel SP2′ may include a second emission area EMA2′ and the non-emission area NEA′ at the periphery of the second emission area EMA2′. The third sub-pixel SP3′ may include a third emission area EMA3′ and the non-emission area NEA′ at the periphery of the third emission area EMA3′.

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′.

The second sub-pixel SP2′ may have an area greater than an area of the first sub-pixel SP1′, and the third sub-pixel SP3′ may have an area greater than the area of the second sub-pixel SP2′. Accordingly, the second emission area EMA2′ may have an area greater than an area of the first emission area EMA1′, and the third emission area EMA3′ may have an area greater than the area of the second emission area EMA2′. However, embodiments are not limited thereto. For example, the first and second sub-pixels SP1′ and SP2′ may have the same area (e.g., substantially the same area), and the third sub-pixel SP3′ may have an area greater than the area of each of the first and second sub-pixels SP1′ and SP2′. As such, the areas of the first to third sub-pixels SP1′ to SP3′ may be variously modified in one or more embodiments.

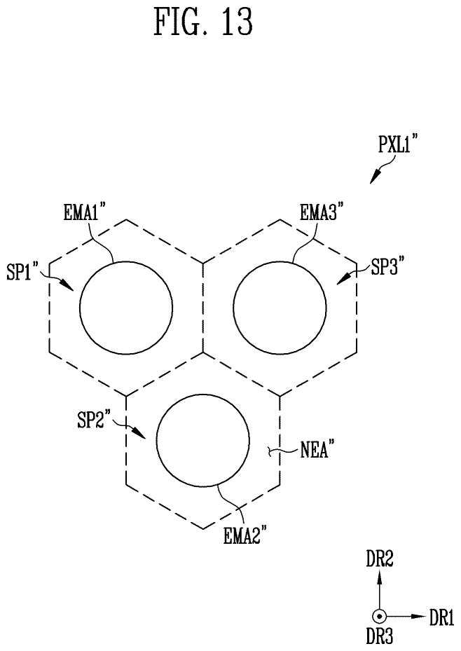

FIG. 13 is a plan view illustrating aspects of the one of the pixels shown in FIG. 5 according to some embodiments.

Referring to FIG. 13, a first sub-pixel SP1″ may include a first emission area EMA1″ and a non-emission area NEA″ at the periphery of the first emission area EMA1″. A second sub-pixel SP2″ may include a second emission area EMA2″ and the non-emission area NEA″ at the periphery of the second emission area EMA2″. A third sub-pixel SP3″ may include a third emission area EMA3″ and the non-emission area NEA″ at the periphery of the third emission area EMA3″.

The first to third sub-pixels SP1″ to SP3″ may have polygonal shapes when viewed in the third direction DR3 (e.g., in a plan view). For example, the shapes of the first to third sub-pixels SP1″ to SP3″ may be hexagonal shapes.

The first to third emission areas EMA1″ to EMA3″ may have circular shapes when viewed in the third direction DR3 (e.g., in a plan view). However, embodiments are not limited thereto. For example, each of the first to third emission areas EMA1″ to EMA3″ may have a polygonal shape.

The first and third sub-pixels SP1″ and SP3″ may be arranged in the first direction DR1. The second sub-pixel SP2″ may be in a direction (or diagonal direction) inclined by an acute angle, based on the second direction DR2, with respect to the first sub-pixel SP1″.

The arrangements of the sub-pixels, which are shown in FIGS. 6, 12, and 13, are merely illustrative, and embodiments are not limited thereto. Each pixel may include two or more sub-pixels, and the sub-pixels may be arranged in one or more suitable manners. Each of the sub-pixels may have one or more suitable shapes, and an emission area EMA of the sub-pixel may have one or more suitable shapes.

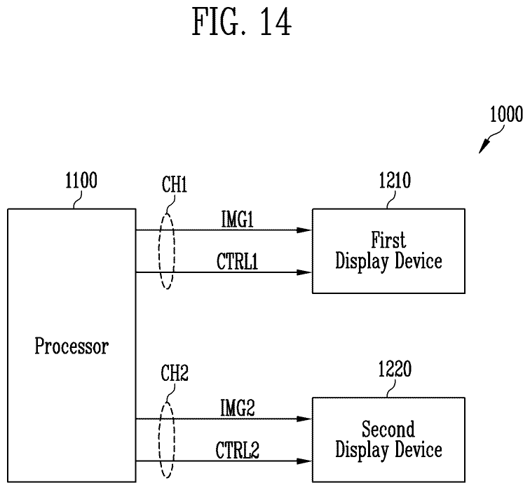

FIG. 14 is a block diagram illustrating aspects of a display system according to some embodiments.

Referring to FIG. 14, a display system 1000 may include a processor 1100 and one or more display devices 1210 and 1220.

The processor 1100 may perform various tasks and various calculations. In one or more embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

In FIG. 14, it is illustrated that the display system 1000 includes first and second display devices 1210 and 1220. The processor 1100 may be connected to the first display device 1210 through a first channel CH1, and be connected to the second display device 1220 through a second channel CH2.

Through the first channel CH1, the processor 1210 may be configured to transmit first image data IMG1 and a first control signal CTRL1 to the first display device 1210. The first display device 1210 may be configured to display an image, based on the first image data IMG1 and the first control signal CTRL1. The first display device 1210 may be configured identically or nearly identically to the display device 100 described with reference to FIG. 1. The first image data IMG1 and the first control signal CTRL1 may be respectively provided as the input image data IMG and the control signal CTRL, which are shown in FIG. 1.

Through the second channel CH2, the processor 1100 may be configured to transmit second image data IMG2 and a second control signal CTRL2 to the second display device 1220. The second display device 1220 may be configured to display an image, based on the second image data IMG2 and the second control signal CTRL2. The second display device 1220 may be configured identically or nearly identically to the display device 100 described with reference to FIG. 1. The second image data IMG2 and the second control signal CTRL2 may be respectively provided as the image data IMG and the control signal CTRL, which are shown in FIG. 1.

The display system 1000 may include a computing system for providing an image display function, such as a portable computer, a mobile phone, a smartphone, a tablet personal computer (PC), a smart watch, a watch phone, a portable multimedia player (PMP), a navigation system, or an ultra mobile computer (UMPC). The display system 1000 may include at least one of a head mounted display (HMD) device, a virtual reality (VR) device, a mixed reality (MR) device, or an augmented reality (AR) device.

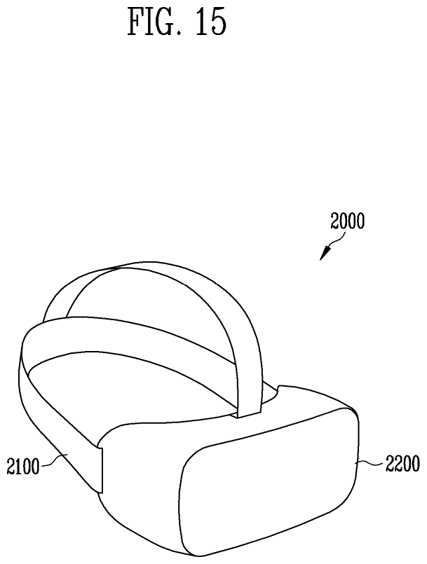

FIG. 15 is a perspective view illustrating an application example of the display system shown in FIG. 14.

Referring to FIG. 15, the display system 1000 shown in FIG. 14 may be applied to a head mounted display device 2000. The head mounted display device 2000 may be a wearable electronic device which can be worn on a head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band, used to fix the head mounted display device 2000 to the head of the user. The horizontal band may be configured to surround (e.g., to be around) a side portion of the head of the user, and the vertical band may be configured to surround (e.g., to be around) an upper portion of the head of the user. However, embodiments are not limited thereto. For example, the head mounting band 2100 may be implemented in the form of a glasses frame, a helmet or the like.

The display device accommodating case 2200 may accommodate the first and second display devices 1210 and 1220 shown in FIG. 14. The display device accommodating case 2200 may further accommodate the processor 1100 shown in FIG. 14.

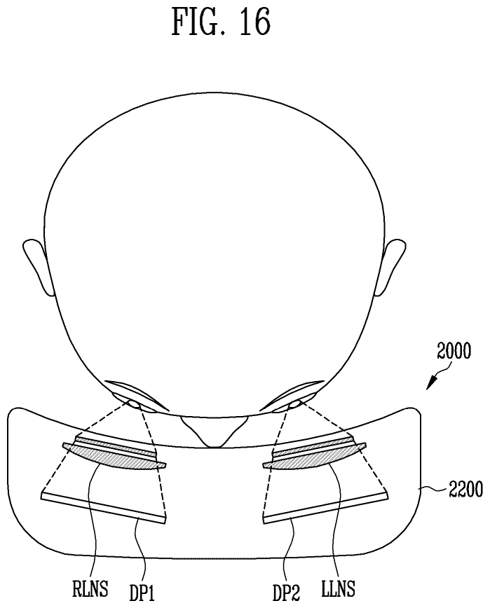

FIG. 16 is a view illustrating the head-mounted display device shown in FIG. 15, which is worn by a user.

Referring to FIG. 16, a first display panel DP1 of the first display device 1210 and a second display panel DP2 of the second display device 1220 may be in the head mounted display device 2000. The head mounted display device 2000 may further include one or more lenses LLNS and RLNS.

In the display device accommodating case 2200, a right-eye lens RLNS may be between the first display panel DP1 and a right eye of the user. In the display device accommodating case 2200, a left-eye lens LLNS may be between the second display panel DP2 and a left eye of the user.

An image outputted from the first display panel DP1 may be viewed by the right eye of the user through the right-eye lens RLNS. The right-eye lens RLNS may be configured to refract light emitted from the first display panel DP1 to face the right eye of the user. The right-eye lens RLNS may perform an optical function for adjusting a viewing distance between the first display panel DP1 and the right eye of the user.

An image outputted from the second display panel DP2 may be viewed by the left eye of the user through the left-eye lens LLNS. The left-eye lens LLNS may be configured to refract light emitted from the second display panel DP2 to face the left eye of the user. The left-eye lens LLNS may perform an optical function for adjusting a viewing distance between the second display panel DP2 and the left eye of the user.

In one or more embodiments, each of the right-eye lens RLNS and the left-eye lens LLNS may include an optical lens having a pancake-shaped section. In one or more embodiments, each of the right-eye lens RLNS and the left-eye lens LLNS may include a multi-channel lens including sub-areas having different optical characteristics. Each display panel may be configured to output images respectively corresponding to the sub-areas of the multi-channel lens, and the outputted images may be viewed by the user while respectively being passed through corresponding sub-areas.

Continuously, a method of manufacturing the display device in accordance with the above-described embodiments will be described in more detail.

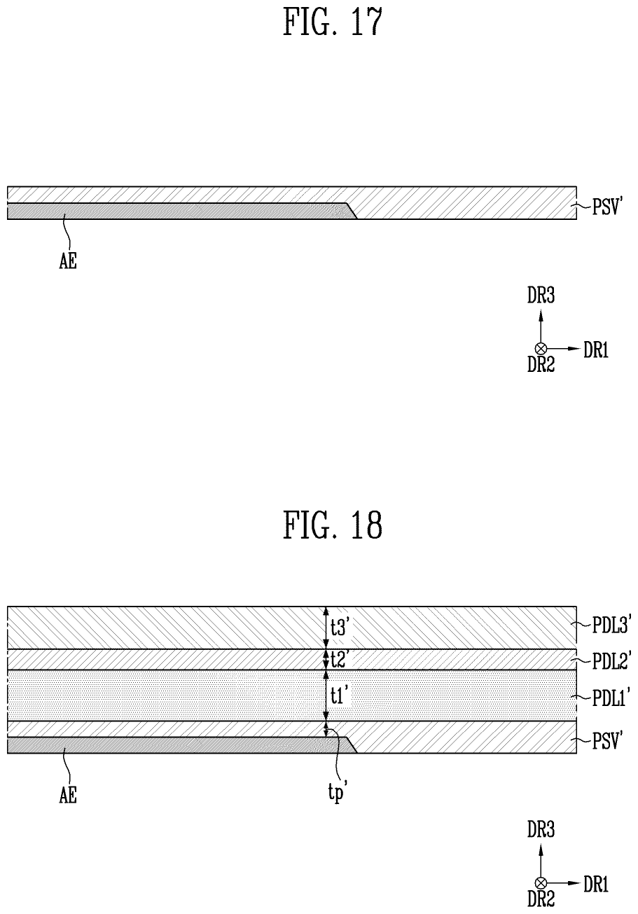

FIGS. 17 to 24 are cross-sectional views illustrating aspects of a method of manufacturing a display device according to some embodiments of the present disclosure. FIGS. 17 to 24 are cross-sectional views illustrating a method of manufacturing the display device shown in FIGS. 1 to 16. For convenience of description, configurations shown in FIGS. 17 to 24 are briefly illustrated, and detailed reference numerals may not be provided.

Referring to FIG. 17, first, a sacrificial layer PSV′ is formed on an anode electrode AE. The sacrificial layer PSV′ may be formed on (e.g., directly on) the anode electrode AE. The sacrificial layer PSV′ may include (e.g., may be formed of) aluminum or an aluminum alloy. The sacrificial layer PSV′ may cover the anode electrode AE, thereby preventing or reducing damage to the anode electrode AE in a subsequent process.

Referring to FIGS. 18 to 21, subsequently, a pixel defining layer PDL is formed on the sacrificial layer PSV′. Specifically, as shown in FIG. 18, a first layer PDL1′, a second layer PDL2′, and a third layer PDL3′ are sequentially formed. The first layer PDL1′ may be formed on (e.g., directly on) the sacrificial layer PSV′. A thickness t1′ of the first layer PDL1′ in the third direction DR3 may be formed thicker than a thickness tp′ of the sacrificial layer PSV′ in the third direction DR3. That is, the first layer PDL1′ may have a thickness t1′ in the third direction DR3 greater than a thickness tp′ of the sacrificial layer PSV′.

The second layer PDL2′ may be formed on (e.g., directly on) the first layer PDL1′. A thickness t2′ of the second layer PDL2′ in the third direction DR3 may be formed thinner than the thickness t1′ of the first layer PDL1′ in the third direction DR3. That is, the second layer PDL2′ may have a thickness t2′ in the third direction DR3 less than a thickness t1′ of the first layer PDL1′. The thickness t2′ of the second layer PDL2′ in the third direction DR3 may be formed thicker than the thickness tp′ of the sacrificial layer PSV′ in the third direction DR3, but the present disclosure is not necessarily limited thereto. For example, the second layer PDL2′ may have a thickness t2′ in the third direction DR3 greater than a thickness tp′ of the sacrificial layer PSV′.

The third layer PDL3′ may be formed on (e.g., directly on) the second layer PDL2′. A thickness t3′ of the third layer PDL3′ in the third direction DR3 may be formed thicker than the thickness t2′ of the second layer PDL2′ in the third direction DR3, but the present disclosure is not necessarily limited thereto. For example, the third layer PDL3′ may have a thickness t3′ in the third direction DR3 greater than a thickness t2′ of the second layer PDL2′.

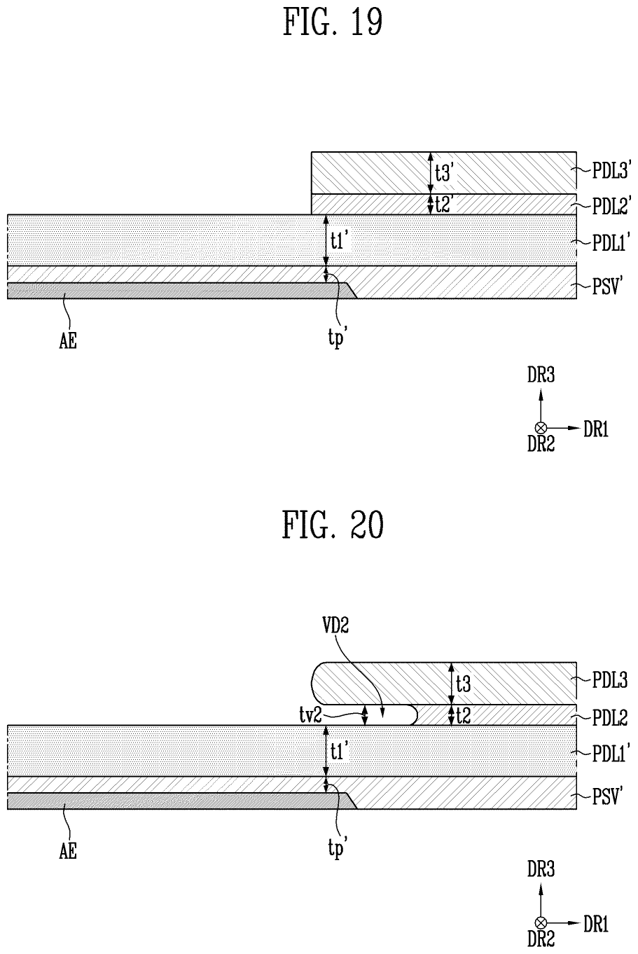

Referring to FIGS. 19 and 20, subsequently, the second layer PDL2′ and the third layer PDL3′ are etched, thereby forming a second pixel defining layer PDL2 and a third pixel defining layer PDL3. For example, after the second layer PDL2′ and the third layer PDL3′ are simultaneously etched as shown in FIG. 19, an undercut structure of the second layer PDL2′ may be formed, thereby forming the second pixel defining layer PDL2 and the third pixel defining layer PDL3.

The second pixel defining layer PDL2 may include an opening overlapping with the anode electrode AE in the third direction DR3. The third pixel defining layer PDL3 may include an opening overlapping with the anode electrode AE in the third direction DR3. A width of the opening of the third pixel defining layer PDL3 in the first direction DR1 may be formed smaller than a width of the opening of the second pixel defining layer PDL2 in the first direction DR1, but the present disclosure is not necessarily limited thereto.

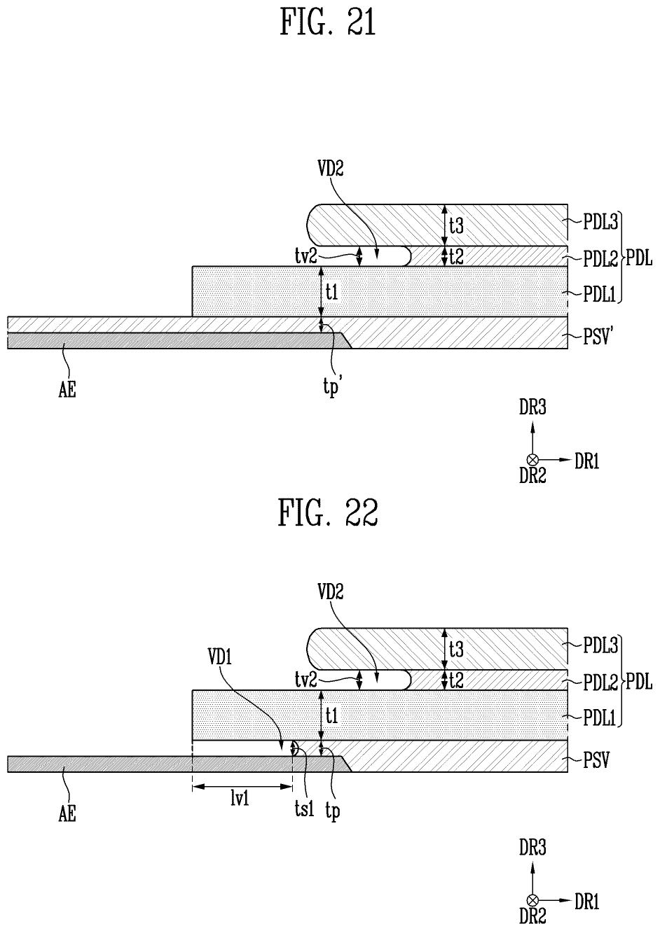

Referring to FIG. 21, subsequently, the first layer PDL1′ is etched, thereby forming a first pixel defining layer PDL1. The first pixel defining layer PDL1 may include an opening overlapping with the anode electrode AE in the third direction DR3. A width of the opening of the first pixel defining layer PDL1 in the first direction DR1 may be formed smaller than the width of the opening of the second pixel defining layer PDL2 in the first direction DR1, but the present disclosure is not necessarily limited thereto. The anode electrode AE may be protected by the sacrificial layer PSV′ in a process of etching the first layer PDL1′. A second void VD2 may be formed between the first pixel defining layer PDL1 and the third pixel defining layer PDL3. For example, a bottom surface of the second void VD2 may be defined by the first pixel defining layer PDL1. A top surface of the second void VD2 may be defined by the third pixel defining layer PDL3. A side surface of the second void VD2 may be defined by the second pixel defining layer PDL2. The second void VD2 may cause a discontinuity to be formed in a light emitting structure EMS (see FIG. 7) between first to third sub-pixels SP1 to SP3 (see FIG. 7). The light emitting structure EMS formed on the pixel defining layer PDL may be at least partially cut or bent by the second void VD2. For example, at least one charge generation layer included in the light emitting structure EMS may be cut by the second void VD2. As such, portions of the light emitting structure EMS, which are included in the first to third sub-pixels SP1 to SP3, may be at least partially separated from each other due to the second void VD2. In other words, the second void VD2 may at least partially separate portions of the light emitting structure EMS. Accordingly, in an operation of the display panel DP, a current leaked from each of the first to third sub-pixels SP1 to SP3 to a sub-pixel adjacent thereto through layers included in the light emitting structure EMS can be decreased. Thus, first to third light emitting elements LD1 to LD3 (see FIG. 7) can operate with relatively high reliability, which has been described above.

Referring to FIGS. 22 to 24, subsequently, a protective layer PSV is formed by etching the sacrificial layer PSV′. The protective layer PSV may include an opening exposing the anode electrode AE. A width of the opening of the protective layer PSV in the first direction DR1 may be greater than the width of the opening of the first pixel defining layer PDL1 in the first direction DR1. A width of the protective layer PSV in the first direction DR1 may be smaller than a width of the first pixel defining layer PDL1 in the first direction DR1.

A first void VD1 may be formed between the anode electrode AE and the pixel defining layer PDL (e.g., the first pixel defining layer PDL1). For example, a bottom surface of the first void VD1 may be defined by the anode electrode AE. A top surface of the first void VD1 may be defined by the first pixel defining layer PDL1. A side surface of the first void VD1 may be defined by the protective layer PSV.

In a process of forming the protective layer PSV by etching the sacrificial layer PSV′, at least a portion of the pixel defining layer PDL (e.g., the first pixel defining layer PDL1) may be on the anode electrode AE. For example, an edge of the first pixel defining layer PDL1 may be on the anode electrode AE in a process of forming the opening of the protective layer PSV. Accordingly, one area of the first pixel defining layer PDL, which overlaps with the opening of the protective layer PSV in the third direction DR3, may have a slope on the anode electrode AE. That is, one of the first pixel defining layer PDL1, which protrudes from the protective layer PSV, may have at least a partial slope on the anode electrode AE. As such, as the edge of the first pixel defining layer PDL1 is on the anode electrode AE, a distance between the edge of the first pixel defining layer PDL1 and the anode electrode AE can be minimized or reduced. Accordingly, the light emitting structure EMS and/or a cathode electrode (see FIG. 7) can be prevented from being disconnected by an undercut structure of the protective layer PSV, which has been described above.

In order for the edge of the first pixel defining layer PDL1 to be more easily arranged in the process of forming the protective layer PSV, a width Iv1 of the first pixel defining layer PDL1 protruding from the protective layer PSV in the first direction DR1 (or a width of the first void VD1 in the first direction DR1) may be formed greater than a thickness tp of the protective layer PSV in the third direction DR3. However, the width Iv1 of the first pixel defining layer PDL1 protruding from the protective layer PSV in the first direction DR1 (or the width of the first void VD1 in the first direction DR1) is not necessarily limited thereto, and may be variously changed within a range in which the edge of the first pixel defining layer PDL1 can be easily land.

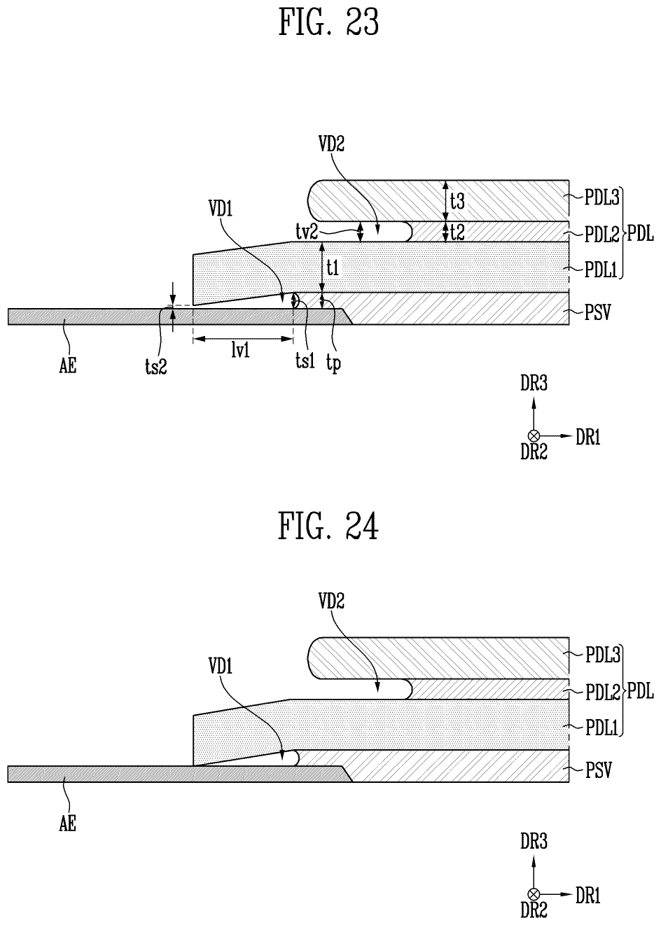

As shown in FIG. 23, the edge of the first pixel defining layer PDL1 may be spaced and/or apart (e.g., spaced apart) from the anode electrode AE in the third direction DR3. In order to prevent or reduce instances of the disconnection caused by the undercut structure, a distance between the edge of the first pixel defining layer PDL1 and the anode electrode AE in the third direction DR3 may be formed as 200 Å or less. In one or more embodiments, as shown in FIG. 24, the edge of the first pixel defining layer PDL1 may be in contact with the anode electrode AE. As such, when the edge of the first pixel defining layer PDL1 is in contact (e.g., direct contact) with the anode electrode AE as the edge of the first pixel defining layer PDL1 is arranged (e.g., completely arranged), the disconnection caused by the undercut structure can be more effectively prevented or reduced.

As described above, when the one area of the first pixel defining layer PDL1, which protrudes from the protective layer PSV, has a slope on the anode electrode AE, the top surface of the first void VD1 may have a slope. A thickness ts1 of a first side of the first void VD1 in the third direction DR3 may be formed greater than a thickness ts2 of a second side of the first void VD1 in the third direction DR3. The thickness ts1 of a first side of the first void VD1 in the third direction DR3 may be equal to the thickness tp of the protective layer PSV in the third direction DR3.

Subsequently, the light emitting structure EMS may formed on the anode electrode AE and the pixel defining layer PDL, and the cathode electrode CE and the like may be formed on the light emitting structure EMS, thereby completing the display device shown in FIGS. 1 to 16.

As described above, as the edge of the first pixel defining PDL1 is arranged on the anode electrode AE, the distance between the edge of the first pixel defining layer PDL1 and the anode electrode AE can be minimized or reduced, so that the light emitting structure EMS and/or the cathode electrode CE can be prevented from being disconnected by the undercut structure of the protective layer or the first void. Moreover, the light emitting structure EMS is at least partially separated by the second void VD2, so that a current leaked to an adjacent sub-pixel can be decreased, thereby improving the reliability of the display device.

According to some embodiments of the present disclosure, damage of an anode electrode can be prevented or reduced using a protective layer, and disconnection of a light emitting structure or the like due to an undercut structure of the protective layer can be prevented or reduced as an edge of the pixel defining layer is on the anode electrode.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims, and their equivalents.

What is claimed is:

1. A display device comprising:
a first electrode;
a protective layer on the first electrode;
a first pixel defining layer on the protective layer;
a first void between the first electrode and the first pixel defining layer;
a second pixel defining layer on the first pixel defining layer;
a third pixel defining layer on the second pixel defining layer;
a second void between the first pixel defining layer and the third pixel defining layer; and
a light emitting structure on the first electrode, the first pixel defining layer, the second pixel defining layer, and the third pixel defining layer,
wherein a thickness of a first side of the first void is greater than a thickness of a second side of the first void.

2. The display device of claim 1, wherein the thickness of the first side of the first void is equal to a thickness of the protective layer.

3. The display device of claim 1, wherein a thickness of the second void is greater than the thickness of the first side of the first void.

4. The display device of claim 1, wherein a width of the first void is greater than a thickness of the protective layer.

5. The display device of claim 1, wherein an edge of the first pixel defining layer is spaced apart from the first electrode.

6. The display device of claim 5, wherein a distance between the edge of the first pixel defining layer and the first electrode is 200 Å or less.

7. The display device of claim 1, wherein an edge of the first pixel defining layer is in contact with the first electrode.

8. The display device of claim 1, wherein the first side of the first void is defined by the protective layer.

9. The display device of claim 1, wherein a first side of the second void is defined by the second pixel defining layer.

10. The display device of claim 1, wherein a second side of the second void is defined by the light emitting structure.

11. The display device of claim 1, wherein the light emitting structure is at least partially separated by the second void.

12. A method of manufacturing a display device, the method comprising:
forming a sacrificial layer on a first electrode;
forming a pixel defining layer on the sacrificial layer;
forming a protective layer by forming an opening exposing the first electrode on the sacrificial layer; and
forming a light emitting structure on the first electrode and the pixel defining layer,
wherein, in the forming of the protective layer, at least a portion of the pixel defining layer is on the first electrode.

13. The method of claim 12, wherein a first void is formed between the first electrode and the pixel defining layer.

14. The method of claim 13, wherein a width of the first void is formed greater than a thickness of the protective layer.

15. The method of claim 12, wherein the sacrificial layer includes aluminum or an aluminum alloy.

16. The method of claim 12, wherein the forming of the pixel defining layer includes:
sequentially forming a first layer, a second layer, and a third layer on the sacrificial layer;
forming a second pixel defining layer and a third pixel defining layer by etching the second layer and the third layer; and
forming a first pixel defining layer by etching the first layer.

17. The method of claim 16, wherein a second void is formed between the first pixel defining layer and the third pixel defining layer.

18. The method of claim 17, wherein the light emitting structure is at least partially separated by the second void.

19. The method of claim 16, wherein, in the forming of the protective layer, the first pixel defining layer is on the first electrode.

20. The method of claim 16, wherein, in the forming of the protective layer, an edge of the first pixel defining layer is in contact with the first electrode.

21. A display system comprising:
a display device comprising:
a first electrode;
a protective layer on the first electrode;
a first pixel defining layer on the protective layer;
a first void between the first electrode and the first pixel defining layer;
a second pixel defining layer on the first pixel defining layer;
a third pixel defining layer on the second pixel defining layer;
a second void between the first pixel defining layer and the third pixel defining layer; and
a light emitting structure on the first electrode, the first pixel defining layer, the second pixel defining layer, and the third pixel defining layer,
wherein a thickness of a first side of the first void is greater than a thickness of a second side of the first void.

22. The display system of claim 21, wherein the display system is at least one selected from the group consisting of a portable computer, a mobile phone, a smartphone, a tablet personal computer (PC), a smart watch, a watch phone, a portable multimedia player (PMP), a navigation system, an ultra mobile computer (UMPC) a head mounted display (HMD) device, a virtual reality (VR) device, a mixed reality (MR) device, and an augmented reality (AR) device.
